(19) United States
(12) Patent Application Publication
(10) Pub. No.: US 2025/0253162 A1
(43) Pub. Date: Aug. 7, 2025

(54) ETCHANT COMPOSITION, METHOD OF MANUFACTURING SEMICONDUCTOR DEVICE USING THE SAME, AND SEMICONDUCTOR DEVICE

(71) Applicant: Samsung Electronics Co., Ltd., Suwon-si (KR)

(72) Inventors: Sangwan KIM, Suwon-si (KR); Geonmin RO, Seoul (KR); Gayoung SONG, Suwon-si (KR); Younsug YOO, Seoul (KR); Jungmin OH, Suwon-si (KR); Wook CHANG, Seoul (KR); Sangwon BAE, Suwon-si (KR)

(73) Assignees: Samsung Electronics Co., Ltd., Suwon-si (KR); OCI Company Ltd., Seoul (KR)

(21) Appl. No.: 18/818,736

(22) Filed: Aug. 29, 2024

(30) Foreign Application Priority Data
Feb. 2, 2024 (KR) 10-2024-0016906

(51) Int. Cl. H01L 21/3213; H01L 29/66

(52) U.S. Cl. CPC H01L 21/32135; H10D 30/025

(57) ABSTRACT

A method of manufacturing a semiconductor device may include preparing a semiconductor structure; forming a slit recessed downward in a vertical direction from a top surface of the semiconductor structure, wherein a length of the slit in the vertical direction may be greater than a width of the slit in a horizontal direction; forming a conductive layer filling at least a portion of the slit, wherein the conductive layer may include titanium nitride, and a seam may be included in the conductive layer; and performing a first etching process using an etchant composition to etch the conductive layer. A conductive pattern may be formed inside the slit from the conductive layer due to the first etching process. The oxidizing agent may include periodic acid. The additive may include nitric acid, acetic acid, or a combination thereof.

### CROSS-REFERENCE TO RELATED APPLICATION

This application is based on and claims priority under 35 U.S.C. § 119 to Korean Patent Application No. 10-2024-0016906, filed on Feb. 2, 2024, in the Korean Intellectual Property Office, the disclosure of which is incorporated by reference herein in its entirety.

### BACKGROUND

Inventive concepts relate to an etchant composition, a method of manufacturing a semiconductor device using the same, and a semiconductor device, and more particularly, to an etchant composition for etching conductive patterns, a method of manufacturing a semiconductor device using the same, and a semiconductor device.

Semiconductor devices are in the spotlight as important elements in the electronics industry due to characteristics such as miniaturization, multifunctionalization, and/or low manufacturing cost. An information storage device among semiconductor devices may store logic data. With the development of the electronics industry, information storage devices are more highly integrated. As a result, the line widths of elements constituting the information storage device are reduced.

In addition, with the high integration of information storage devices, high reliability of information storage devices is required. However, due to high integration, the reliability of the information storage device may deteriorate. Therefore, many studies are being conducted to improve the reliability of information storage devices.

### SUMMARY

Inventive concepts provide an etchant composition capable of controlling the size of a seam, a method of manufacturing a semiconductor device using the same, and a semiconductor device.

Inventive concepts provide a semiconductor device with improved electrical characteristics and reliability, and a manufacturing method thereof.

According to an embodiment of inventive concepts, a method of manufacturing a semiconductor device may include preparing a semiconductor structure; forming a slit recessed downward in a vertical direction from a top surface of the semiconductor structure, wherein a length of the slit in the vertical direction may be greater than a width of the slit in a horizontal direction; forming a conductive layer filling at least a portion of the slit, wherein the conductive layer may include titanium nitride, and a scam may be included in the conductive layer; performing a first etching process using an etchant composition to etch the conductive layer, wherein the etchant composition may include an oxidizing agent, an etching agent, an additive, and a solvent, a conductive pattern may be formed inside the slit from the conductive layer due to the first etching process, and a vertical level of a top surface of the conductive pattern may be lower than a vertical level of a top surface of the semiconductor structure; and performing a second etching process on the conductive pattern. The oxidizing agent may include a periodic acid, and the additive may include nitric acid, acetic acid, or a combination thereof.

According to an embodiment of inventive concepts, a method of manufacturing a semiconductor device may include preparing a substrate; forming active patterns by patterning an upper portion of the substrate; forming a groove recessed downward in a vertical direction from a top surface of each of the active patterns, wherein a length of the groove in the vertical direction may be greater than a width of the groove in a horizontal direction; sequentially forming a gate dielectric layer and a gate electrode layer in the groove, the gate electrode layer including titanium nitride and being formed on the gate dielectric layer, the gate electrode layer extending on a top surface of each of the active patterns, and a seam being included in the gate electrode layer; performing a first etching process using an etchant composition to etch the gate electrode layer, wherein the etchant composition may include an oxidizing agent, an etching agent, an additive, and a solvent, a gate electrode pattern may be formed from the gate electrode layer by the first etching process, and a vertical level of a top surface of the gate electrode pattern may be lower than a vertical level of a top surface of each of the active patterns; and performing a second etching process on the gate electrode pattern.

According to an embodiment of inventive concepts, a method of manufacturing a semiconductor device may include forming active patterns by patterning an upper portion of the substrate; forming a groove recessed downward in a vertical direction from a top surface of each of the active patterns, wherein a length of the groove in the vertical direction may be greater than a width of the groove in a first horizontal direction; sequentially forming a gate dielectric layer and a gate electrode layer in the groove, the gate electrode layer including titanium nitride and being formed on the gate dielectric layer, the gate electrode layer extending on a top surface of each of the active patterns, and the gate electrode layer including a seam in the gate electrode layer; performing a first etching process on the gate electrode layer using an etchant composition, wherein the etchant composition may include an oxidizing agent, an etching agent, an additive, and a solvent, a gate electrode pattern is formed from the gate electrode layer by the first etching process, the electrode pattern extends in a second horizontal direction crossing the first horizontal direction, and a vertical level of a top surface of the gate electrode pattern is lower than a vertical level of a top surface of each of the active patterns; performing a second etching process on the gate electrode pattern; forming a gate capping layer on the gate electrode pattern; forming line structures extending in the first horizontal direction on a top surface of the gate capping layer, wherein the line structures may be spaced apart from each other in the second horizontal direction; and forming insulating fences between the line structures adjacent to each other in the second horizontal direction.

### BRIEF DESCRIPTION OF THE DRAWINGS

Embodiments of inventive concepts will be more clearly understood from the following detailed description taken in conjunction with the accompanying drawings in which:

FIGS. 1A to 1E are cross-sectional views illustrating a method of manufacturing a semiconductor device according to embodiments;

FIGS. 2A to 2D are cross-sectional views illustrating a method of manufacturing a semiconductor device according to embodiments;

FIG. 3 is a plan view of a semiconductor device according to embodiments;

FIG. 4 is an enlarged view of a boundary between a cell region and a core region of FIG. 3, and is an enlarged plan view of a region PP of FIG. 3;

FIG. 5A is a cross-sectional view taken along line A-A′ of FIG. 4, FIG. 5B is a cross-sectional view taken along line B-B′ of FIG. 4, FIG. 5C is a cross-sectional view taken along line C-C′ of FIG. 4, and FIG. 5D is a cross-sectional view taken along line D-D′ of FIG. 4;

FIGS. 6, 8, 12, 14, 16, and 18 are plan views for describing a method of manufacturing a semiconductor device according to embodiments;

FIGS. 7A, 9A, 10A, 11A, 13A, 15A, 17A, and 19A are cross-sectional views taken along line A-A′ of FIGS. 6, 8, 12, 14, 16, and 18, respectively;

FIGS. 7B, 9B, 10B, 11B, 13B, 15B, 17B, and 19B are cross-sectional views taken along line B-B′ of FIGS. 6, 8, 12, 14, 16, and 18, respectively;

FIGS. 7C, 9C, 10C, 11C, 13C, 15C, 17C, and 19C are cross-sectional views taken along line C-C′ of FIGS. 6, 8, 12, 14, 16, and 18, respectively; and

FIGS. 7D, 9D, 10D, 11D, 13D, 15D, 17D, and 19D are cross-sectional views taken along line D-D′ of FIGS. 6, 8, 12, 14, 16, and 18, respectively.

### DETAILED DESCRIPTION OF THE EMBODIMENTS

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. The notion that elements are “substantially the same” may indicate that the element may be completely the same and may also indicate that the elements may be determined to be the same in consideration of errors or deviations occurring during a process.

Hereinafter, embodiments according to inventive concepts are described with reference to the accompanying drawings.

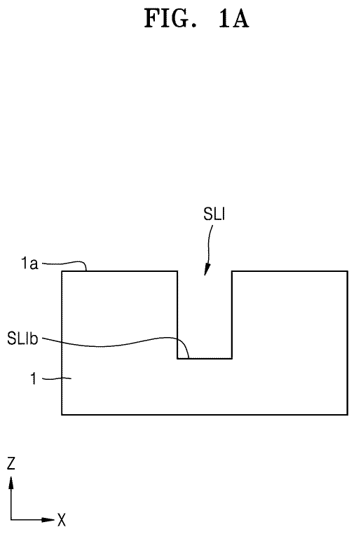

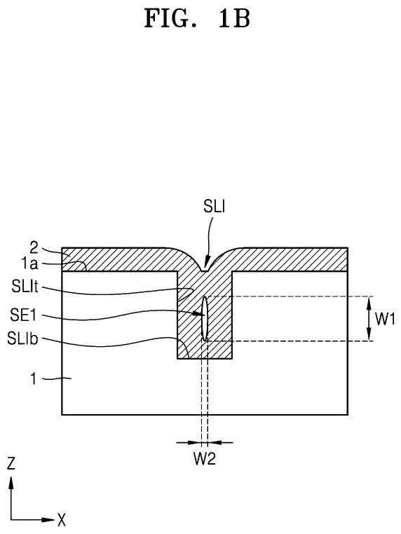

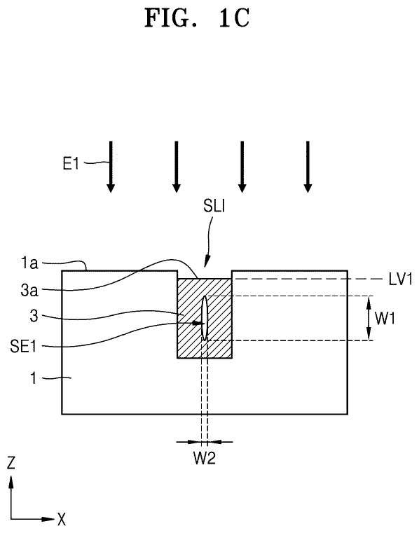

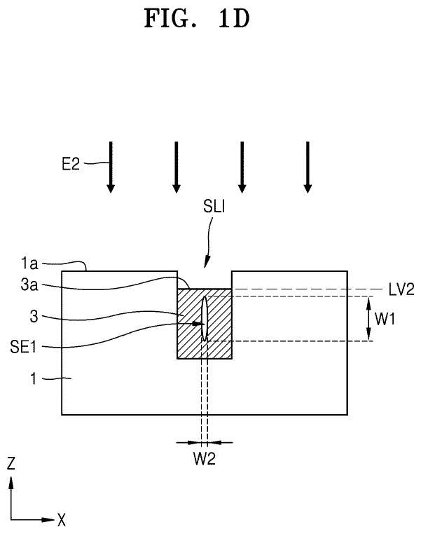

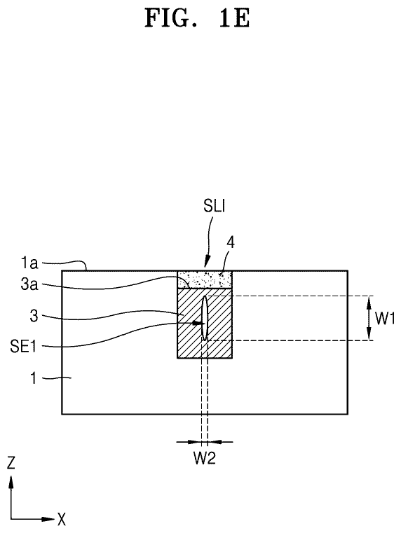

FIGS. 1A to 1E are cross-sectional views illustrating a method of manufacturing a semiconductor device according to embodiments.

Referring to FIG. 1A, a semiconductor structure 1 may be provided. For example, the semiconductor structure 1 may include a semiconductor material. The semiconductor material may include silicon (Si) or germanium (Ge). Alternatively, the semiconductor structure 1 may include a compound semiconductor such as silicon-germanium (SiGe), silicon carbide (SiC), gallium arsenide (GaAs), indium arsenide (InAs), indium gallium arsenide (InGaAs), or indium phosphorus (InP). Alternatively, the semiconductor structure 1 may have a silicon-on-insulator (SOI) structure. For example, the semiconductor structure 1 may include a buried oxide layer (BOX).

As another example, the semiconductor structure 1 may be a device having a specific circuit structure. For example, the semiconductor structure 1 may include a device structure such as Dynamic Random Access Memory (DRAM), NAND Flash, Ferroelectric Random Access Memory (FRAM), Resistive Random Access Memory (RRAM), Phase-Change Random Access Memory (PRAM), Magnetoresistive Random Access Memory (MRAM), an Application Processor (AP), or an Application Specific Integrated Circuit (ASIC).

The semiconductor structure 1 may include a slit SLI cut in the vertical direction Z. The slit SLI may be formed through an etching process on the semiconductor structure 1. The slit SLI may be a portion recessed downward in the vertical direction Z from the top surface of the semiconductor structure 1. A width of the slit SLI in the horizontal direction X may be less than a length of the slit SLI in the vertical direction Z. A vertical level of the bottom surface SLIb of the slit SLI may be lower than a vertical level of a top surface 1a of the semiconductor structure 1.

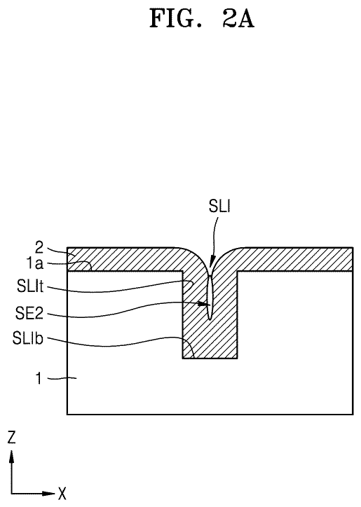

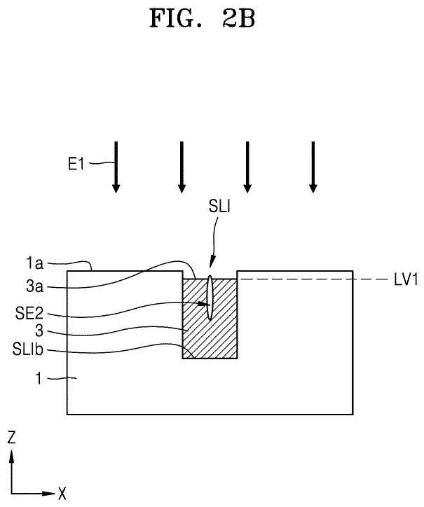

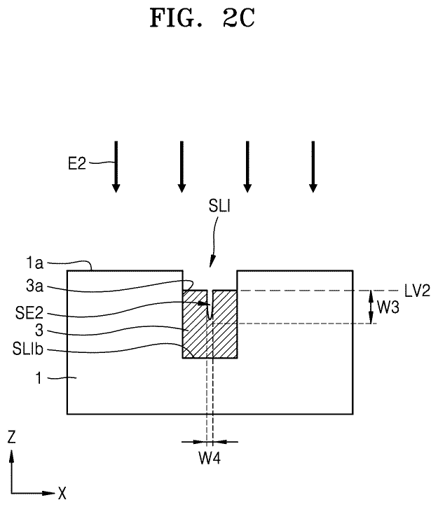

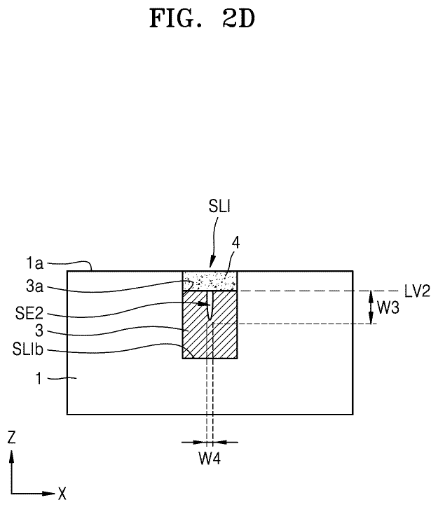

In the present specification, in the description with reference to FIGS. 1A to 2D, the horizontal direction X is defined as one direction parallel to the top surface 1a of the semiconductor structure 1, and the vertical direction Z is defined as a direction perpendicular to the top surface 1a of the semiconductor structure 1.

Referring to FIG. 1B, a conductive layer 2 filling at least a portion of the slit SLI of the semiconductor structure 1 may be formed. The conductive layer 2 may cover the bottom surface SLIb and the inner wall SLIt of the slit SLI. The conductive layer 2 may cover the top surface 1a of the semiconductor structure 1.

A first seam SE1 may be formed inside the conductive layer 2. The first seam SE1 may be an empty space. The first seam SE1 may not be exposed to the outside by the conductive layer 2. The length of the first seam SE1 in the vertical direction Z may be a first width W1. The length of the first seam SE1 in the horizontal direction X may be a second width W2. The first width W1 may be greater than the second width W2. That is, the first seam SE1 may be formed to be longer in the vertical direction Z than in the horizontal direction X.

The conductive layer 2 may be formed using physical vapor deposition (PVD), chemical vapor deposition (CVD), plasma enhanced CVD (PECVD), atomic layer deposition (ALD), or a combination thereof.

The conductive layer 2 may include a conductive material. For example, the conductive layer 2 may include a metal, a metal nitride, or a combination thereof. For example, the conductive layer 2 may include a metal nitride. In an embodiment, the conductive layer 2 may include titanium nitride (TiN).

Referring to FIG. 1C, a first etching process E1 may be performed on the conductive layer 2. The first etching process E1 may be a wet etching process. A portion of the conductive layer 2 may be etched due to the first etching process E1. Due to the first etching process E1, all portions of the conductive layer 2 on the top surface 1a of the semiconductor structure 1 may be etched.

Due to the first etching process E1, a conductive pattern 3 may be formed from the conductive layer 2. After the first etching process E1, a vertical level of a top surface 3a of the conductive pattern 3 may be a first vertical level LV1. The first vertical level LV1 may be lower than a vertical level of the top surface 1a of the semiconductor structure 1.

The etchant composition used to perform the first etching process E1 may include an oxidizing agent, an etching agent, an additive, and a solvent. The etchant composition may include 0.1 to 10 parts by weight of an oxidizing agent, 40 to 90 parts by weight of an etching agent, 0 to 1 part by weight of an additive, and 0 to 50 parts by weight of a solvent, based on 100 parts by weight.

The oxidizing agent included in the etchant composition may oxidize the conductive layer 2 to generate a metal oxide. For example, a metal oxide may include titanium oxide. The oxidizing agent may perform only the function of oxidizing the conductive layer 2. The oxidizing agent may not etch the oxidized conductive layer 2.

For example, the oxidizing agent may include periodic acid, hydrogen peroxide, hydrochloric acid, bromic acid, iodic acid, perchloric acid, hydrofluoric acid, perbromic acid, methanesulfonic acid, paratoluenesulfonic acid, benzensulfonic acid, ammonium persulfate, ammonium nitrate, urea peroxide, or a combination thereof.

The etching agent included in the etchant composition may etch the conductive layer 2 oxidized by the oxidizing agent. The etching agent may perform only a function of etching the oxidized conductive layer 2. The etching agent may not oxidize the conductive layer 2. For example, the etching agent may include phosphoric acid, sulfuric acid, or a combination thereof.

The additive included in the etchant composition may perform a function of controlling the rate at which the oxidized conductive layer 2 is etched by the etching agent. The conductive layer 2 may be limited and/or prevented from being rapidly etched due to the additive. For example, the additive may include acetic acid, nitric acid, or a combination thereof.

The solvent may control the concentrations of the oxidizing agent, the etching agent, and the additive. For example, the solvent may include water.

According to embodiments of inventive concepts, the oxidizing agent contained in the etchant composition may perform only the function of oxidizing the conductive layer 2. In addition, the etching agent included in the etchant composition may perform only the function of etching the oxidized conductive layer 2. Therefore, the rate at which the conductive layer 2 is etched may be adjusted by the etchant composition.

By adjusting the rate at which the conductive layer 2 is etched, the first seam SE1 may not be exposed to the outside while the first etching process E1 is performed. Therefore, the etchant composition used in the first etching process E1 may be limited and/or prevented from penetrating the first seam SE1. Accordingly, since the size of the first seam SE1 may be controlled, the conductive pattern 3 may be sufficiently filled in the slit SLI.

In addition, the curvature of the top surface 3a of the conductive pattern 3 may be alleviated by adjusting the etching rate of the conductive layer 2 due to the etchant composition used in the first etching process E1. That is, the top surface 3a of the conductive pattern 3 may be flattened.

Referring to FIG. 1D, a second etching process E2 may be performed on the conductive pattern 3. The second etching process E2 may be a wet etching process. A portion of the conductive pattern 3 may be etched due to the second etching process E2. Due to the second etching process E2, the top surface 3a of the conductive pattern 3 may have a second vertical level LV2. The second vertical level LV2 may be lower than the first vertical level LV1.

Although not shown, a plurality of slits SLI formed in the semiconductor structure 1 may be provided. In addition, a conductive pattern 3 may be formed in each of the plurality of slits SLI. In this case, vertical levels of top surfaces 3a of a plurality of conductive patterns 3 may be substantially the same as each other through the second etching process E2. That is, the uniformity of the top surfaces 3a of the plurality of conductive patterns 3 may be improved due to the second etching process E2.

During the first etching process E1 and the second etching process E2, the first seam SE1 may not be exposed to the outside. Therefore, the etchant used in the second etching process E2 may be limited and/or prevented from penetrating the first seam SE1. For the above reasons, while the second etching process E2 is performed, the size of the first seam SE1 may be limited and/or prevented from increasing. That is, when the etchant composition according to inventive concepts is used, the size of the first seam SE1 inside the conductive pattern 3 may be controlled.

Referring to FIG. 1E, a capping pattern 4 may be formed on the conductive pattern 3. The capping pattern 4 may include a single layer or a plurality of layers. The capping pattern 4 may include an insulating material. Alternatively, the capping pattern 4 may include a semiconductor material. When the capping pattern 4 includes a plurality of layers, a single material or a plurality of materials constituting the capping pattern 4 may be included.

Since the uniformity of the top surface 3a of the conductive pattern 3 is improved due to the second etching process E2, the capping pattern 4 may be easily formed.

FIGS. 2A to 2D are cross-sectional views illustrating a method of manufacturing a semiconductor device according to embodiments. Hereinafter, redundant descriptions with those given with reference to FIGS. 1A to 1E are omitted or briefly described, and differences are described in detail.

Referring to FIG. 2A, a conductive layer 2 filling at least a portion of the slit SLI of FIG. 1A may be formed. The conductive layer 2 may cover the top surface 1a of the semiconductor structure 1. The conductive layer 2 may cover the bottom surface SLIb and the inner wall SLIt of the slit SLI.

A second seam SE2 may be formed inside the conductive layer 2. The second scam SE2 may be an empty space. The second seam SE2 may be exposed to the outside. The second seam SE2 may be formed to be longer in the vertical direction Z than in the horizontal direction X.

Referring to FIG. 2B, a first etching process E1 may be performed on the conductive layer 2. The first etching process E1 may be a wet etching process. The etchant composition used to perform the first etching process E1 may be the same as the etchant composition described with reference to FIGS. 1A to 1E.

While the first etching process E1 is performed, the size of the second seam SE2 may not increase. This may be due to the fact that the oxidation of the conductive layer 2 and the etching of the oxidized conductive layer 2 occur separately due to the etchant composition used when performing the first etching process E1. Therefore, the size of the second seam SE2 may be controlled. Due to the first etching process E1, a conductive pattern 3 may be formed from the conductive layer 2.

If the rate at which the conductive layer 2 is etched is not adjusted when the first etching process E1 is performed, the etchant composition may flow into the second seam SE2 due to gravity. In this case, the conductive layer 2 may be excessively etched.

According to embodiments of inventive concepts, the oxidizing agent contained in the etchant composition may perform only the function of oxidizing the conductive layer 2. In addition, the etching agent included in the etchant composition may perform only the function of etching the oxidized conductive layer 2. In addition, the rate at which the conductive layer 2 is oxidized by the oxidizing agent may be higher than the rate at which the conductive layer 2 oxidized by the etching agent is etched.

The volume of the conductive layer 2 oxidized by the oxidizing agent included in the etchant composition may be greater than the volume of the conductive layer 2 before oxidation. Accordingly, the second seam SE2 exposed to the outside in FIG. 2A may be blocked from the outside by the oxidized conductive layer 2 having an increased volume. In addition, the oxidized conductive layer 2 may be etched by an etching agent included in the etchant composition. In this case, since the oxidizing rate is faster than the etching rate, the second seam SE2 may still be blocked from the outside while the first etching process E1 is performed. Therefore, the etchant composition may be limited and/or prevented from penetrating the second seam SE2. For the above reasons, the size of the second seam SE2 may be controlled. In particular, when the length of the second seam SE2 in the vertical direction Z is greater than the length of the second seam SE2 in the horizontal direction X, the effect of inventive concepts may be greater.

Referring to FIG. 2C, a second etching process E2 may be performed on the conductive pattern 3. The second etching process E2 may be a wet etching process.

While the second etching process E2 is performed, the size of the second seam SE2 may not increase. In other words, the size of the second seam SE2 may be controlled. The reason that the size of the second seam SE2 may be controlled may be due to the fact that the size of the second seam SE2 does not increase when the first etching process E1 is performed. That is, since the size of the second seam SE2 is small, the etchant used in performing the second etching process E2 may not penetrate the second seam SE2.

After the second etching process E2 is performed, a length of the second seam SE2 in the vertical direction Z may be a third width W3, and a length of the second seam SE2 in the horizontal direction X may be a fourth width W4. The third width W3 may be greater than the fourth width W4.

Referring to FIG. 2D, a capping pattern 4 may be formed on the conductive pattern 3.

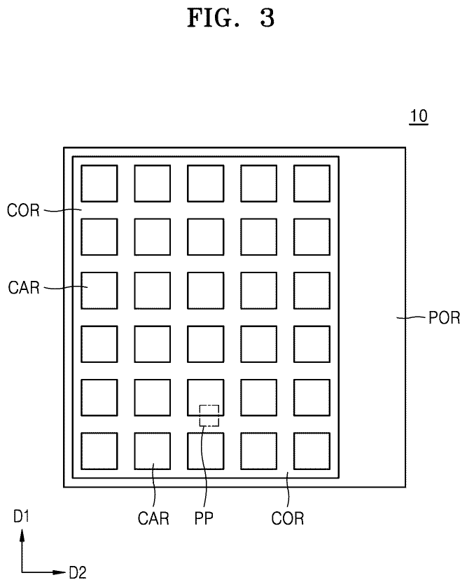

FIG. 3 is a plan view of a semiconductor device according to embodiments;

Referring to FIG. 3, the semiconductor device 10 may include cell regions CAR. The cell regions CAR are regions including a plurality of memory cells, and each cell region CAR may constitute one unit cell block. The cell regions CAR may be spaced apart from each other in the first horizontal direction D1 and the second horizontal direction D2.

A core region COR may be provided between the cell regions CAR adjacent to each other. A sense amplifier and a write driver may be provided in the core region COR. A peripheral circuit region POR may be provided at a side of the cell regions CAR. The peripheral circuit region POR may include a row decoder, a column decoder, etc.

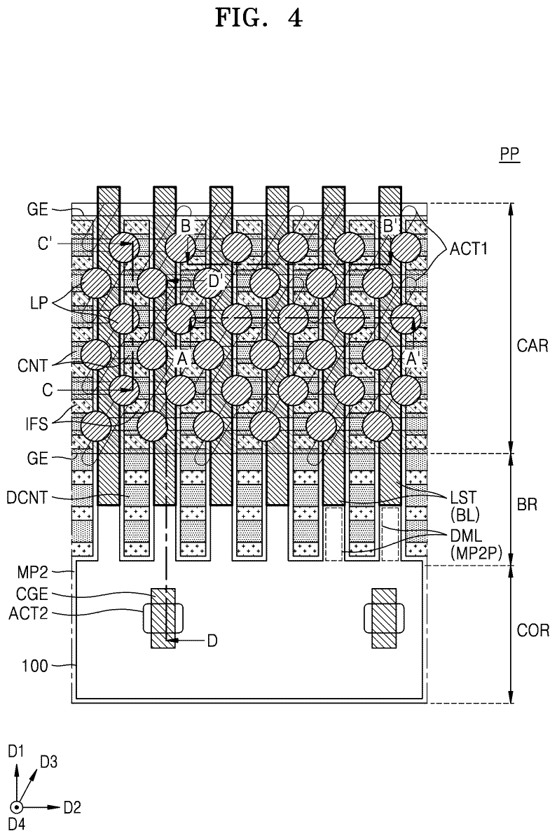

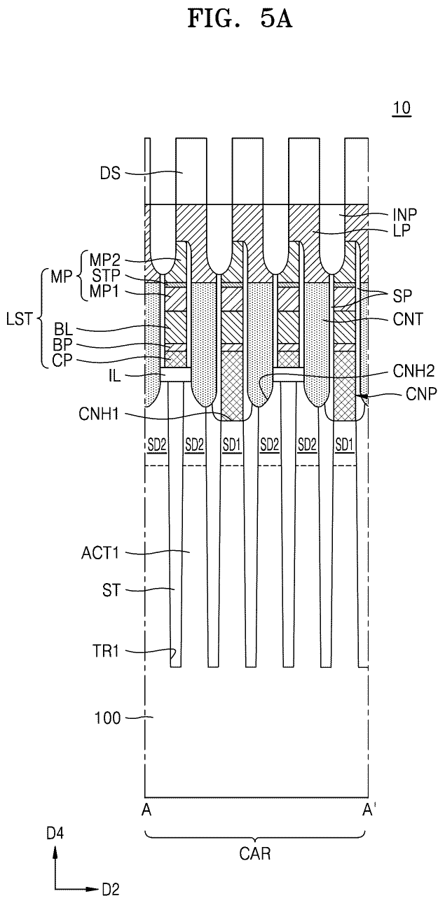

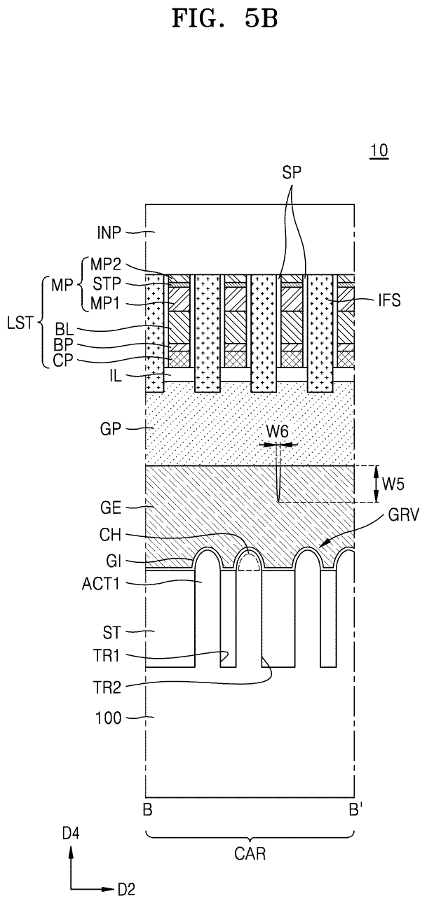

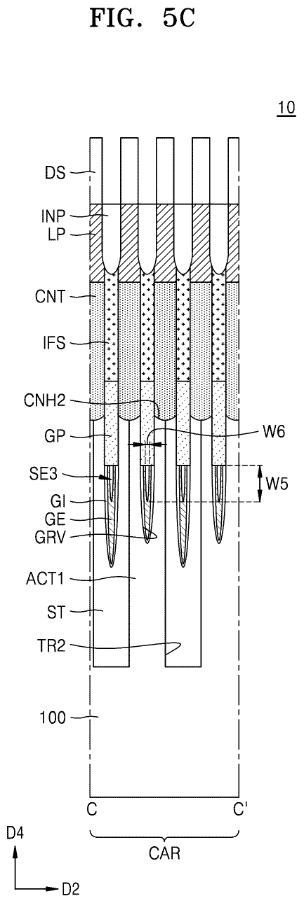

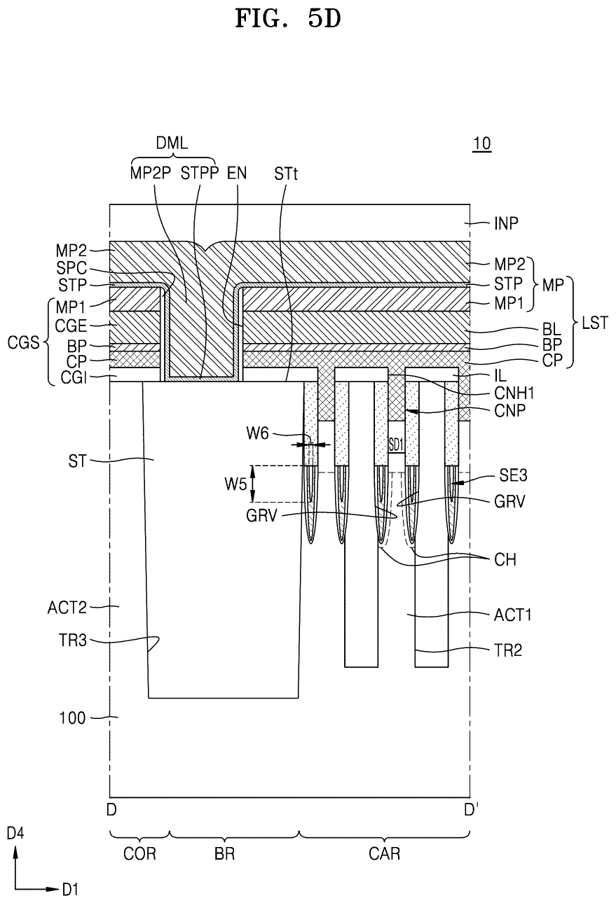

FIG. 4 is an enlarged view of a boundary between a cell region and a core region of FIG. 3, and is an enlarged plan view of a region PP of FIG. 3. FIG. 5A is a cross-sectional view taken along line A-A′ of FIG. 4, FIG. 5B is a cross-sectional view taken along line B-B′ of FIG. 4, FIG. 5C is a cross-sectional view taken along line C-C′ of FIG. 4, and FIG. 5D is a cross-sectional view taken along line D-D′ of FIG. 4.

Referring to FIG. 4, a substrate 100 including a cell region CAR, a boundary region BR, and a core region COR may be provided. The cell region CAR may be a region in which a plurality of memory cells are provided. The boundary region BR may be arranged between the cell region CAR and the core region COR. The boundary region BR may be a region for buffering a process difference due to the difference between a structure in the cell region CAR and a structure in the core region COR. The boundary region BR may connect a structure in the cell region CAR with a structure in the core region COR.

The substrate 100 may be a bulk silicon substrate, an SOI substrate, a germanium substrate, a germanium-on-insulator (GOI) substrate, a silicon-germanium substrate, or a substrate of an epitaxial thin layer obtained by performing selective epitaxial growth (SEG).

Hereinafter, the cell region CAR is described in detail with reference to FIGS. 4 and 5A to 5D. Referring to FIGS. 4 and 5A to 5D, device isolation layers ST defining first active patterns ACT1 may be provided in the cell region CAR of the substrate 100. The first active patterns ACT1 may be formed by patterning an upper portion of the substrate 100.

Each of the first active patterns ACT1 may extend in the third horizontal direction D3 parallel to the top surface of the substrate 100. In other words, each of the first active patterns ACT1 may have a major axis in the third horizontal direction D3. The first active patterns ACT1 may be two-dimensionally arranged in the first horizontal direction D1 and the second horizontal direction D2. The first active patterns ACT1 may be spaced apart from each other in the third horizontal direction D3.

The width of each of the first active patterns ACT1 may decrease in a direction toward the vertical direction D4 of the substrate 100. In other words, the width of each of the first active patterns ACT1 may decrease as the distance from the bottom surface of the substrate 100 increases.

In the present specification, in the description with reference to FIGS. 3 to 19D, the first horizontal direction D1 is defined as one direction parallel to the top surface of the substrate 100. The second horizontal direction D2 is defined as a direction perpendicular to the first horizontal direction D1 and parallel to the top surface of the substrate 100. The third horizontal direction D3 is defined in a direction that intersects the first horizontal direction D1 and the second horizontal direction D2 and is parallel to the top surface of the substrate 100. The vertical direction D4 is defined as a direction perpendicular to the top surface of the substrate 100.

Each of a first trench TR1 and a second trench TR2 may be defined between the first active patterns ACT1. The device isolation layer ST may fill each of the first trench TR1 and the second trench TR2 between the first active patterns ACT1. The first trench TR1 may be defined between a pair of the first active patterns ACT1 adjacent to each other in the second horizontal direction D2. The second trench TR2 may be defined between a pair of the first active patterns ACT1 adjacent to each other in the third horizontal direction D3.

A distance between the pair of first active patterns ACT1 adjacent to each other in the second horizontal direction D2 may be less than a distance between the pair of first active patterns ACT1 adjacent to each other in the third horizontal direction D3. The second trench TR2 may be deeper than the first trench TR1. A bottom of the second trench TR2 may be lower than a bottom of the first trench TR1.

Each of the first active patterns ACT1 may include a first source/drain region SD1 and a pair of second source/drain regions SD2. The first source/drain region SD1 and the pair of the second source/drain regions SD2 may be arranged above each of the first active patterns ACT1.

The first source/drain region SD1 may be positioned between the pair of the second source/drain regions SD2. In a plan view, the second source/drain region SD2, the first source/drain region SD1, and the second source/drain region SD2 may be sequentially arranged in the third horizontal direction D3.

A pair of grooves GRV may be arranged in each of the first active patterns ACT1. Each of the grooves GRV may be arranged between the first source/drain region SD1 and the second source/drain region SD2.

The groove GRV may extend downward from the top surface of the first active pattern ACT1 toward the bottom surface of the substrate 100 while inserted into the upper portion of the first active pattern ACT1. The groove GRV may be a portion recessed downward in the vertical direction D4 from the top surface of the first active pattern ACT1 or the top surface of the device isolation layer ST. A width of the groove GRV in the first horizontal direction D1 may be less than a length of the groove GRV in the vertical direction D4. The bottom of the groove GRV may be higher than the bottom surface of the first trench TR1 and the bottom surface of the second trench TR2.

Each of the first active patterns ACT1 may further include a pair of channel regions CH. The pair of channel regions CH may be arranged above each of the first active patterns ACT1.

In a plan view, the channel region CH may be arranged between the first source/drain region SD1 and the second source/drain region SD2. The channel region CH may be located below the groove GRV. Accordingly, the channel region CH may be located lower than the first and second source/drain regions SD1 and SD2.

Gate electrode patterns GE crossing the first active patterns ACT1 and the device isolation layer ST may be arranged. The gate electrode patterns GE may be arranged in the grooves GRV, respectively. The gate electrode patterns GE may extend parallel to each other in the second horizontal direction D2. The pair of gate electrode patterns GE may be arranged on the pair of channel regions CH of the first active pattern ACT1.

In a plan view, the gate electrode pattern GE may be arranged between the first source/drain region SD1 and the second source/drain region SD2. The top surface of the gate electrode pattern GE may be lower than the top surface of the first active pattern ACT1 (e.g., the top surface of the first source/drain region SD1 or the top surface of the second source/drain region SD2).

Referring to FIG. 5D, the upper portion of the gate electrode pattern GE may be closer to the first source/drain region SD1 of the first active pattern ACT1 than the channel region CH. The lower portion of the gate electrode pattern GE may be closer to the channel region CH than the first source/drain region SD1 of the first active pattern ACT1. The gate electrode pattern GE may correspond to a word line of a memory cell.

Referring back to FIGS. 4 and 5A to 5D, a gate dielectric pattern GI may be arranged between the gate electrode pattern GE and the first active pattern ACT1. A gate capping layer GP may be provided on the gate electrode pattern GE. The gate capping layer GP may cover a top surface of the gate electrode pattern GE. The top surface of the gate capping layer GP may be coplanar with the top surface of the first active pattern ACT1.

The gate electrode pattern GE may include conductive metal nitride (e.g., titanium nitride or tantalum nitride) and/or metal materials (e.g., titanium, tantalum, tungsten, copper, or aluminum). In an embodiment, the gate electrode pattern GE may include titanium nitride.

The gate dielectric pattern GI may include a silicon oxide layer, a silicon nitride layer, a silicon oxynitride layer, and/or a high dielectric constant material. For example, the high dielectric constant material may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc nibium acid salt, or a combination thereof.

The gate capping layer GP may include a silicon oxide layer, a silicon nitride layer, and/or a silicon oxynitride layer. Alternatively, the gate capping layer GP may include polysilicon. The gate capping layer GP may include a single layer or a multilayer. When the gate capping layer GP includes a multilayer, the gate capping layer GP may include a plurality of materials.

A buffer layer IL may be provided on the substrate 100. The buffer layer IL may include first contact holes CNH1 exposing the first source/drain regions SD1 of the first active patterns ACT1. In an embodiment of inventive concepts, the buffer layer IL may include a first insulating layer and a second insulating layer sequentially stacked. The second insulating layer may have a greater dielectric constant than the first insulating layer. For example, the first insulating layer may include a silicon oxide layer, and the second insulating layer may include a silicon oxynitride layer.

Line structures LST extending parallel to each other in the first horizontal direction D1 may be provided on the buffer layer IL. The line structures LST may be arranged in the second horizontal direction D2. In a plan view, the line structures LST may vertically cross the gate electrode patterns GE. A pair of spacers SP may be provided on both sidewalls of each of the line structures LST. The spacers SP may include a silicon oxide layer, a silicon nitride layer, and/or a silicon oxynitride layer.

In an embodiment of inventive concepts, each of the spacers SP may include a first spacer, a second spacer, and a third spacer. The first spacer may directly cover a sidewall of the line structure LST. The second spacer may be arranged between the first spacer and the third spacer. The second spacer may include an insulating material having a dielectric constant lower than those of the first and third spacers. For example, each of the first and third spacers may include a silicon nitride layer, and the second spacer may include a silicon oxide layer. As another example, the second spacer may include air, that is, an air spacer.

Each of the line structures LST may include a conductive pattern CP, a barrier pattern BP, a bit line BL, and a mask pattern MP, which are sequentially stacked. The conductive pattern CP may include a contact portion CNP. The contact portion CNP may be connected to the first source/drain region SD1 while filling the first contact hole CNH1. More specifically, the contact portion CNP may extend toward the bottom surface of the substrate 100 through the buffer layer IL. The contact portion CNP may be in direct contact with the first source/drain region SD1.

The barrier pattern BP may suppress the metallic material of the bit line BL from diffusing into the conductive pattern CP. The bit line BL may be electrically connected to the first source/drain region SD1 through the barrier pattern BP and the conductive pattern CP.

The conductive pattern CP may include a doped semiconductor material (doped silicon, doped germanium, etc.). The barrier pattern BP may include a conductive metal nitride (for example, titanium nitride or tantalum nitride). The bit line BL may include a metallic material (e.g., titanium, tantalum, tungsten, copper, or aluminum).

In the cell region CAR, a first mask pattern MP1, a stopper pattern STP, and a second mask pattern MP2 may constitute a mask pattern MP. In the cell region CAR, the mask pattern MP may include the first mask pattern MP1, the stopper pattern STP, and the second mask pattern MP2. The first mask pattern MP1, the stopper pattern STP, and the second mask pattern MP2 may be sequentially stacked on the bit line BL.

The stopper pattern STP may be arranged between the first mask pattern MP1 and the second mask pattern MP2. Each of the first mask pattern MP1, the stopper pattern STP, and the second mask pattern MP2 may include silicon nitride or silicon oxynitride. For example, the first mask pattern MP1, the stopper pattern STP, and the second mask pattern MP2 may include the same material (e.g., silicon nitride).

Referring to FIGS. 4 and 5B, a plurality of insulating fences IFS may be provided on the gate capping layer GP. Each of the insulating fences IFS may extend through the buffer layer IL to an upper portion of the gate capping layer GP.

The insulating fences IFS may be two-dimensionally arranged in the first horizontal direction D1 and the second horizontal direction D2. Specifically, the insulating fences IFS may be arranged in the second horizontal direction D2 on the gate capping layer GP extending in the second horizontal direction D2. The insulating fences IFS and the line structures LST may be alternately arranged in the second horizontal direction D2. The insulating fences IFS arranged in the second horizontal direction D2 may vertically overlap corresponding ones of the gate electrode patterns GE.

Referring back to FIGS. 4 and 5A to 5D, contacts CNT penetrating the buffer layer IL and connecting the second source/drain regions SD2, respectively, may be provided. Each of the contacts CNT may fill the second contact hole CNH2 formed by partially etching an upper portion of the second source/drain region SD2.

Referring to FIG. 5A, each of the contacts CNT may be in direct contact with the second source/drain region SD2 exposed by the second contact hole CNH2. Each of the contacts CNT may be in contact with a sidewall of the spacer SP and a top surface of the device isolation layer ST. Each of the contacts CNT may be spaced apart from the line structure LST by the spacer SP. Each of the contacts CNT may include a doped semiconductor material (doped silicon, doped germanium, etc.).

Referring to FIG. 4, the contacts CNT may be two-dimensionally arranged in the first horizontal direction D1 and the second horizontal direction D2. Specifically, the contacts CNT and the line structures LST may be alternately arranged in the second horizontal direction D2. The contacts CNT and the insulating fences IFS may be arranged between the line structures LST adjacent to each other. The contacts CNT and the insulating fences IFS between the line structures LST adjacent to each other may be alternately arranged in the first horizontal direction D1.

Referring again to FIGS. 4 and 5A to 5D, landing pads LP connected to the contacts CNT, respectively, may be provided on the contacts CNT. The landing pads LP may be electrically connected to the second source/drain regions SD2, respectively, through the contacts CNT. The landing pads LP may be misaligned with the contacts CNT connected thereto. In other words, the landing pads LP may be horizontally offset from the center of the contacts CNT connected thereto (see FIGS. 2 and 3A). The landing pads LP may include a metallic material (e.g., titanium, tantalum, tungsten, copper, or aluminum).

An insulating pattern INP may be provided on each of the mask patterns MP. The insulating pattern INP in the cell region CAR may define a planar shape of each of the landing pads LP. Adjacent landing pads LP may be separated from each other by the insulating pattern INP.

Data storage elements DS may be provided on the landing pads LP, respectively. Specifically, each of the data storage elements DS may be electrically connected to the second source/drain region SD2 through the landing pad LP and the contact CNT. According to an embodiment, each of the data storage elements DS may be a capacitor that stores data. For example, each of the data storage elements DS may include lower electrodes connected to the landing pads LP, an upper electrode covering the lower electrodes, and a dielectric layer arranged between the lower electrodes and the upper electrode. The upper electrode may be a common electrode covering the lower electrodes in common.

Each of the lower electrodes may have a hollow cylindrical shape. Each of the lower electrodes may include impurity-doped silicon, a metal such as tungsten, or a conductive metal compound such as titanium nitride. The dielectric layer may include a high dielectric constant material such as, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc nibium acid salt, or a combination thereof. The upper electrode may include doped silicon, Ru, RuO, Pt, PtO, Ir, IrO, SRO(SrRuO), BSRO((Ba, Sr)RuO), CRO(CaRuO), BaRuO, La(Sr, Co)O, Ti, TiN, W, WN, Ta, TaN, TiAlN, TiSiN, TaAlN, TaSiN, or a combination thereof.

Hereinafter, the boundary region BR and the core region COR are described in detail with reference to FIGS. 4 and 5D. A third trench TR3 may be defined between the cell region CAR and the core region COR of the substrate 100. In other words, the third trench TR3 may be defined in the boundary region BR of the substrate 100. The device isolation layer ST may fill the third trench TR3.

At least one second active pattern ACT2 may be provided in the core region COR. For example, the third trench TR3 may be defined between the first active pattern ACT1 of the cell region CAR and the second active pattern ACT2 of the core region COR. Although FIG. 4 shows the second active pattern ACT2 in a rectangular shape, embodiments are not limited thereto and may be modified in any shape.

A core gate structure CGS may be provided in the core region COR. The core gate structure CGS may include a core gate insulating layer CGI, a conductive pattern CP, a barrier pattern BP, a core gate electrode CGE, and a first mask pattern MP1, which are sequentially stacked on the second active pattern ACT2. For example, the core gate structure CGS and the second active pattern ACT2 may constitute a transistor of the sense amplifier of the core region COR.

The components of the core gate structure CGS may be formed by substantially the same process as those of the line structure LST in the cell region CAR described above. The components of the core gate structure CGS may be arranged at substantially the same levels as those of the line structure LST, respectively. The core gate insulating layer CGI may correspond to the buffer layer IL. The core gate electrode CGE may correspond to the bit line BL.

In an embodiment, one end of the core gate structure CGS may extend to the device isolation layer ST of the boundary region BR. At least a portion of the core gate structure CGS may vertically overlap the device isolation layer ST filling the third trench TR3 of the boundary region BR.

A sidewall spacer SPC may be provided on a sidewall of the core gate structure CGS. The sidewall spacer SPC may be positioned on the device isolation layer ST of the boundary region BR. The sidewall spacer SPC may include at least one of a silicon oxide layer, a silicon nitride layer, and a silicon oxynitride layer.

Referring to FIG. 5D, one end EN of the line structure LST may extend to the device isolation layer ST of the boundary region BR. A dummy capping pattern DML may be connected to one end EN of the line structure LST.

The dummy capping pattern DML may be provided on the device isolation layer ST in the boundary region BR. The dummy capping pattern DML may include a first portion STPP and a second portion MP2P.

A first portion STPP may be a portion extending from the stopper pattern STP. The first portion STPP may be a portion of the stopper pattern STP. That is, the first portion STPP may be a portion of the stopper pattern STP arranged in the boundary region BR.

Similarly, a second portion MP2P may be a portion in which the second mask pattern MP2 extends. The second portion MP2P may be a portion of the second mask pattern MP2. That is, the second portion MP2P may be a portion of the second mask pattern MP2 arranged in the boundary region BR.

The dummy capping pattern DML may extend from one end EN of the line structure LST toward the core region COR in a direction opposite to the first horizontal direction D1. The dummy capping pattern DML and the line structure LST connected thereto may be aligned with each other in the first horizontal direction D1. The line width of the dummy capping pattern DML may be substantially the same as the line width of the line structure LST connected thereto.

The stopper pattern STP may cover one end EN of the line structure LST in the boundary region BR. The stopper pattern STP may extend onto the core gate structure CGS from the line structure LST while covering the top surface of the device isolation layer ST in the boundary region BR. The stopper pattern STP may cover the sidewall spacer SPC.

The second mask pattern MP2 may be provided on the stopper pattern STP. The second mask pattern MP2 may extend from the cell region CAR through the boundary region BR into the core region COR. The second mask pattern MP2 may be a component constituting the mask pattern MP in the cell region CAR. The second mask pattern MP2 may be referred to as the second portion MP2P of the dummy capping pattern DML in a portion of the boundary region BR.

In a plan view, the second mask pattern MP2 may overlap the line structure LST and the dummy capping pattern DML. The second mask pattern MP2 in the core region COR may have a plate shape overlapping the core region COR.

The insulating pattern INP may be provided on the second mask pattern MP2. Although not shown, at least one metal wiring may be provided in the insulating pattern INP. The metal wiring may electrically connect the bit line BL of the line structure LST with the core gate electrode CGE of the core gate structure CGS.

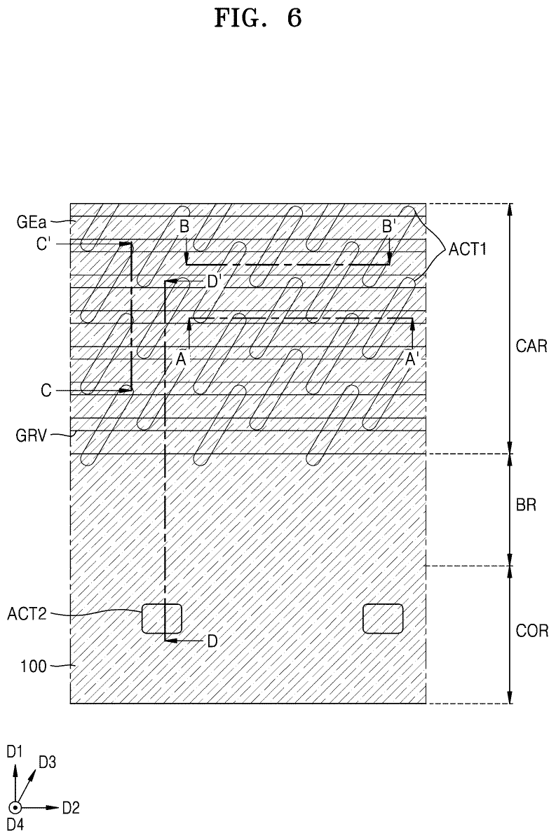

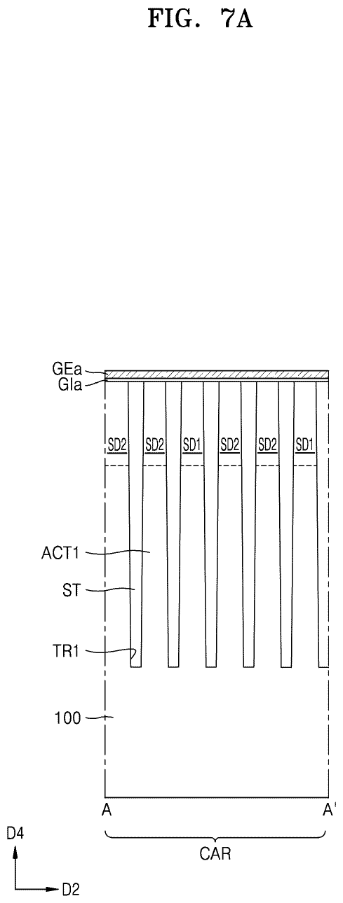

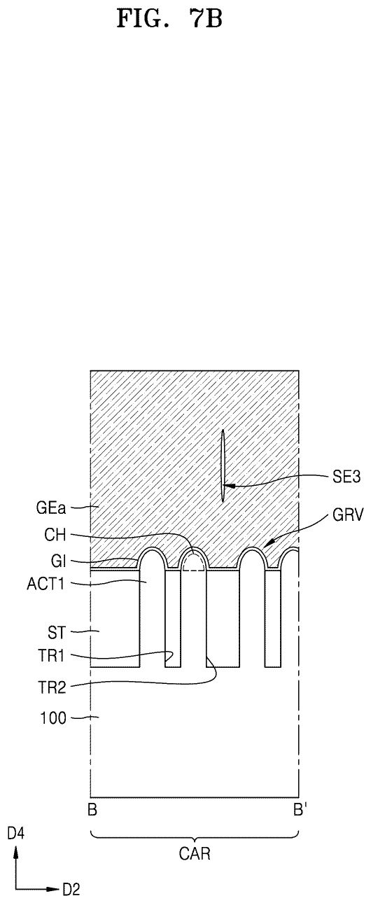

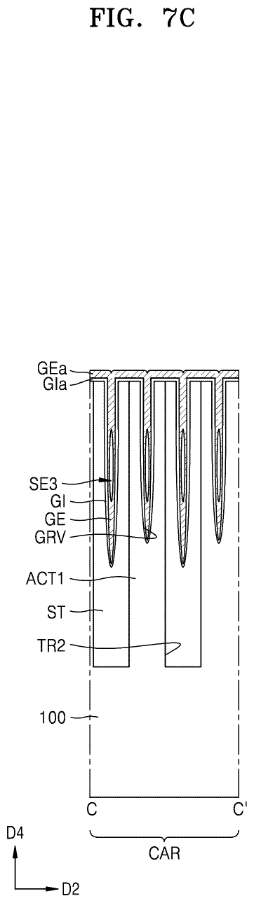

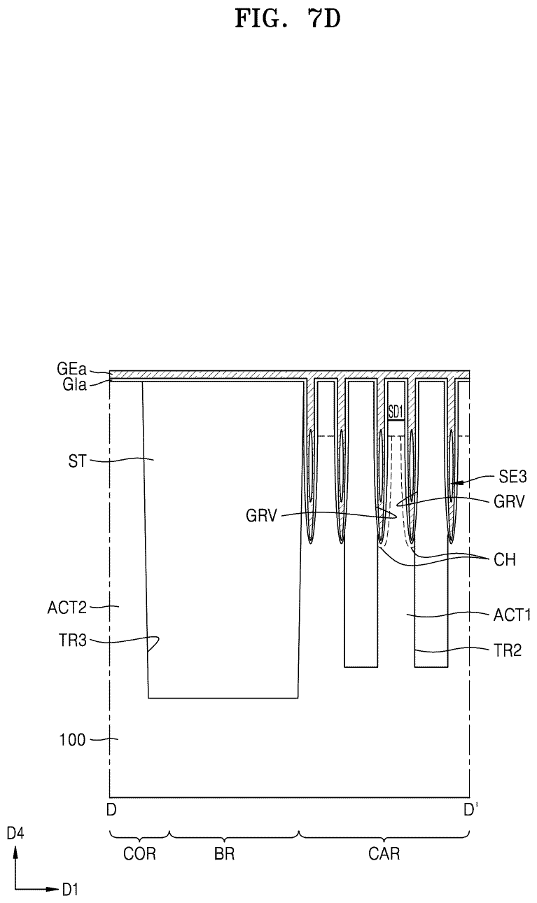

FIGS. 6 to 19D are cross-sectional views illustrating a method of manufacturing a semiconductor device according to embodiments. Specifically, FIGS. 6, 8, 12, 14, 16, and 18 are plan views to describe a method of manufacturing a semiconductor device according to embodiments. FIGS. 7A, 9A, 10A, 11A, 13A, 15A, 17A, and 19A are cross-sectional views taken along line A-A′ of FIGS. 6, 8, 12, 14, 16, and 18, respectively. FIGS. 7B, 9B, 10B, 11B, 13B, 15B, 17B, and 19B are cross-sectional views taken along line B-B′ of FIGS. 6, 8, 12, 14, 16, and 18, respectively. FIGS. 7C, 9C, 10C, 11C, 13C, 15C, 17C, and 19C are cross-sectional views taken along line C-C′ of FIGS. 6, 8, 12, 14, 16, and 18, respectively. FIGS. 7D, 9D, 10D, 11D, 13D, 15D, 17D, and 19D are cross-sectional views taken along line D-D′ of FIGS. 6, 8, 12, 14, 16, and 18, respectively.

Referring to FIGS. 6 and 7A to 7D, a substrate 100 including a cell region CAR, a boundary region BR, and a core region COR may be provided. An upper portion of the substrate 100 may be patterned to form first active patterns ACT1 in the cell region CAR, and form second active patterns ACT2 in the core region COR.

Each of the first active patterns ACT1 may extend in the third horizontal direction D3 parallel to the top surface of the substrate 100. The first active patterns ACT1 may be two-dimensionally arranged in the first horizontal direction D1 and the second horizontal direction D2. The first active patterns ACT1 may be spaced apart from each other in the third horizontal direction D3.

Each of first and second trenches TR1 and TR2 may be formed between the first active patterns ACT1. The first trench TR1 may be formed between a pair of the first active patterns ACT1 adjacent to each other in the second horizontal direction D2. The second trench TR2 may be formed between a pair of the first active patterns ACT1 adjacent to each other in the third horizontal direction D3.

A third trench TR3 may be formed between the first active pattern ACT1 of the cell region CAR and the second active pattern ACT2 of the core region COR. The third trench TR3 may be formed in the boundary region BR and the core region COR.

A device isolation layer ST filling the first to third trenches TR1 to TR3 may be formed. The device isolation layer ST may be formed to cover the first and second active patterns ACT1 and ACT2 while completely filling the first to third trenches TR1 to TR3. A planarization process may be performed on the device isolation layer ST so that the top surfaces of the first and second active patterns ACT1 and ACT2 are exposed.

An ion implantation process may be performed on the first active patterns ACT1 to form a first source/drain region SD1 and a pair of second source/drain regions SD2 above the first active pattern ACT1. The pair of second source/drain regions SD2 may be spaced apart from each other in the third horizontal direction D3 with the first source/drain region SD1 therebetween. For example, the first and second source/drain regions SD1 and SD2 may be doped with the same impurities.

A channel region CH may be defined in the first active pattern ACT1 positioned below the gate electrode pattern GE. In a plan view, the channel region CH may be arranged between the first source/drain region SD1 and the second source/drain region SD2. The gate electrode pattern GE may be provided on the top surface and both sidewalls of the channel region CH.

Grooves GRV may be formed by patterning the first active patterns ACT1 and the device isolation layer ST in the cell region CAR. In a plan view, each of the grooves GRV may have a linear shape extending in the second horizontal direction D2.

The groove GRV may extend downward from the top surface of the first active pattern ACT1 toward the bottom surface of the substrate 100 by inserting into the upper portion of the first active pattern ACT1. The groove GRV may be a portion recessed downward in the vertical direction D4 from the top surface of the first active pattern ACT1 or the top surface of the device isolation layer ST. A width of the groove GRV in the first horizontal direction D1 may be less than a length of the groove GRV in the vertical direction D4. The bottom of the groove GRV may be higher than the bottom surface of the first trench TR1 and the bottom surface of the second trench TR2.

Forming the grooves GRV may include forming a hard mask pattern including openings, and etching the first active patterns ACT1 and the device isolation layer ST, which are exposed by using the hard mask pattern with an etching mask. The grooves GRV may be formed to be shallower than the first trenches TR1.

A gate dielectric layer GIa and a gate electrode layer GEa may be sequentially formed in each of the grooves GRV. Specifically, the gate dielectric layer GIa may be conformally formed in the groove GRV. The gate dielectric layer GIa may include a silicon oxide layer, a silicon nitride layer, a silicon oxynitride layer, and/or a high dielectric constant material.

The gate electrode layer GEa filling at least a portion of the groove GRV may be formed on the gate dielectric layer GIa. The gate electrode layer GEa may include a conductive metal nitride and/or a metal material. In an embodiment, the gate electrode layer GEa may include titanium nitride. The gate electrode layer GEa may extend to the top surface of the device isolation layer ST, the top surfaces of the first active patterns ACT1, and the top surfaces of the second active patterns ACT2.

A third seam SE3 may be formed in the gate electrode layer GEa. The third seam SE3 may not be exposed to the outside by the gate electrode layer GEa. Alternatively, although not shown, the third seam SE3 may be exposed to the outside like the second seam SE2 in FIG. 2A. This may vary depending on the environment in which the semiconductor device 10 is manufactured.

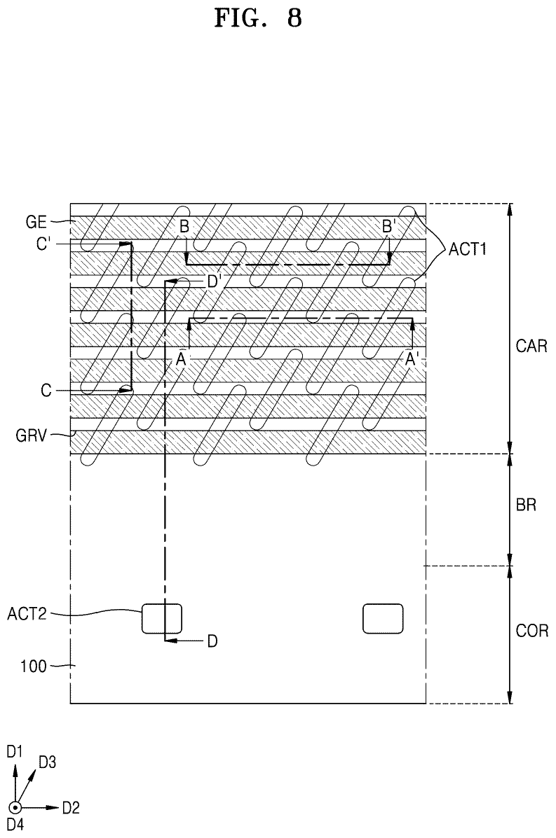

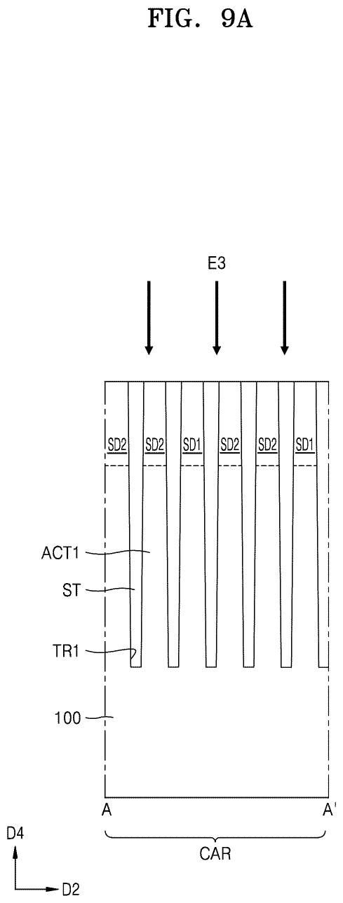

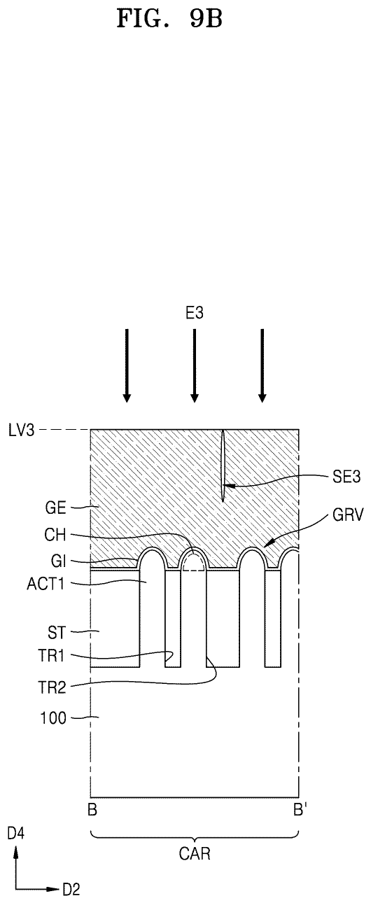

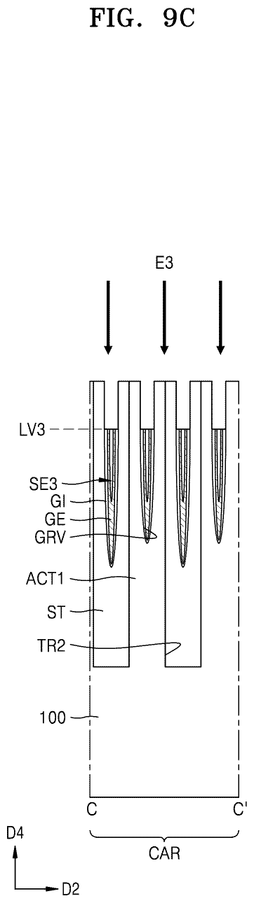

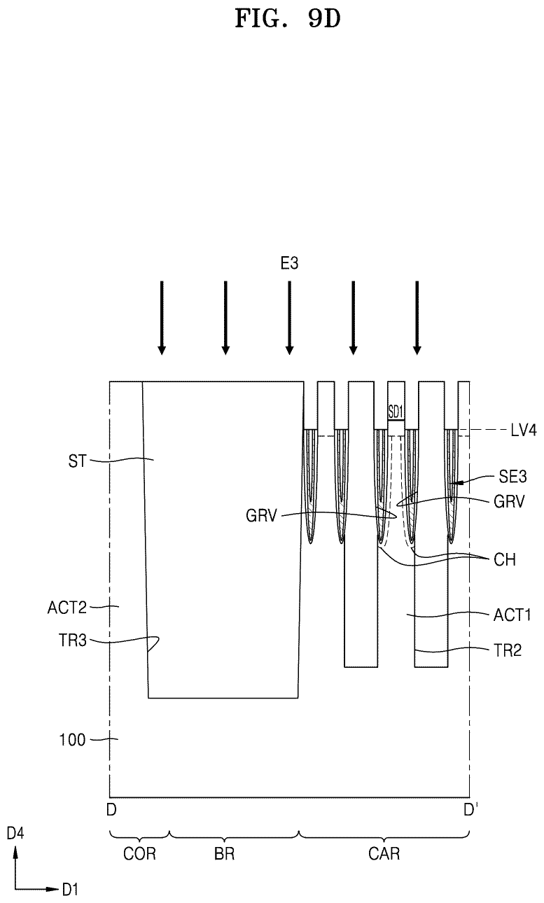

Referring to FIGS. 8 and 9A to 9D, a third etching process E3 may be performed on the gate electrode layer GEa and the gate dielectric layer GIa. The third etching process E3 may be a wet etching process. A portion of the gate electrode layer GEa and a portion of the gate dielectric layer GIa may be etched due to the third etching process E3. Due to the third etching process E3, both the portion of the gate electrode layer GEa and the portion of the gate dielectric layer GIA that were on the top surface of the device isolation layer ST, the top surfaces of the first active patterns ACT1, and the top surfaces of the second active patterns ACT2 may be etched.

Due to the third etching process E3, a gate dielectric pattern GI may be formed from the gate dielectric layer GIa, and a gate electrode pattern GE may be formed from the gate electrode layer GEa. After the third etching process E3, a vertical level of the top surface of the gate electrode pattern GE may be a third vertical level LV3. The third vertical level LV3 may be lower than vertical levels of the top surface of the device isolation layer ST, the top surfaces of the first active patterns ACT1, and the top surfaces of the second active patterns ACT2.

The etchant composition used to perform the third etch process E3 may include an oxidizing agent, an etching agent, an additive, and a solvent. The etchant composition may include 0.1 to 10 parts by weight of an oxidizing agent, 40 to 90 parts by weight of an etching agent, 0 to 1 part by weight of an additive, and 0 to 50 parts by weight of a solvent, based on 100 parts by weight.

The oxidizing agent included in the etchant composition may oxidize the gate electrode layer GEa to generate a metal oxide. For example, a metal oxide may include titanium oxide. The oxidizing agent may perform only a function of oxidizing the gate electrode layer GEa. The oxidizing agent may not etch the oxidized gate electrode layer GEa.

For example, the oxidizing agent may include periodic acid, hydrogen peroxide, hydrochloric acid, bromic acid, iodic acid, perchloric acid, hydrofluoric acid, perbromic acid, methanesulfonic acid, paratoluenesulfonic acid, benzensulfonic acid, ammonium persulfate, ammonium nitrate, urea peroxide, or a combination thereof.

The etching agent included in the etchant composition may etch the gate electrode layer GEa oxidized by the oxidizing agent. The etching agent may perform only a function of etching the oxidized gate electrode layer GEa. The etching agent may not oxidize the gate electrode layer GEa. For example, the etching agent may include phosphoric acid, sulfuric acid, or a combination thereof.

The additive included in the etchant composition may perform a function of controlling the rate at which the oxidized gate electrode layer GEa is etched by the etching agent. The gate electrode layer GEa may be limited and/or prevented from being rapidly etched due to the additive. For example, the additive may include acetic acid, nitric acid, or a combination thereof.

The solvent may control the concentrations of the oxidizing agent, the etching agent, and the additive. For example, the solvent may include water.

According to embodiments of inventive concepts, the oxidizing agent contained in the etchant composition may perform only the function of oxidizing the gate electrode layer GEa. In addition, the etching agent included in the etchant composition may perform only the function of etching the oxidized gate electrode layer GEa. Therefore, the rate at which the gate electrode layer GEa is etched may be adjusted by the etchant composition.

When the rate at which the gate electrode layer GEa is etched is not adjusted when the third etching process E3 is performed, the etchant composition may flow into the third seam SE3 due to gravity. In this case, the gate electrode layer GEa may be excessively etched.

Since the rate at which the gate electrode layer GEa is etched is adjusted, the third seam SE3 may not be exposed to the outside while the third etching process E3 is performed. Therefore, the etchant composition used in the third etching process E3 may be limited and/or prevented from penetrating the third seam SE3. Accordingly, since the size of the third seam SE3 may be controlled, the gate electrode pattern GE may be sufficiently filled in the groove GRV. For the above reasons, electrical characteristics and reliability of the semiconductor device 10 may be improved.

Since the etching rate of the gate electrode layer GEa is adjusted due to the etchant composition used in the third etching process E3, the curvature of the top surface of the gate electrode pattern GE may be alleviated. That is, the top surface of the gate electrode pattern GE may be flat.

Alternatively, after the third etching process E3, the third seam SE3 may be exposed to the outside. However, even in this case, for reasons similar to those described with reference to FIG. 2B, the etchant composition may be limited and/or prevented from penetrating the third seam SE3. Accordingly, the size of the third seam SE3 may be controlled. That is, since the gate electrode pattern GE may be sufficiently filled in the groove GRV, electrical characteristics and reliability of the semiconductor device 10 may be improved.

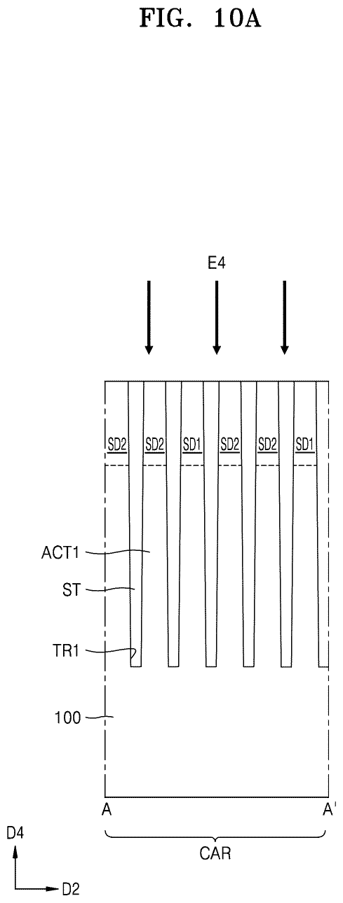

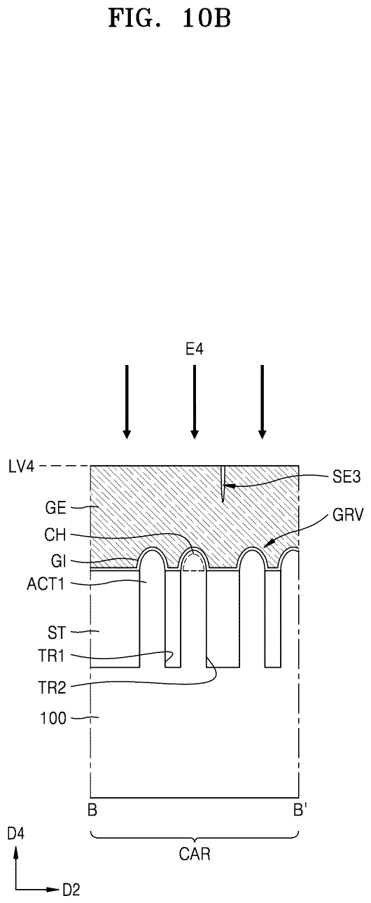

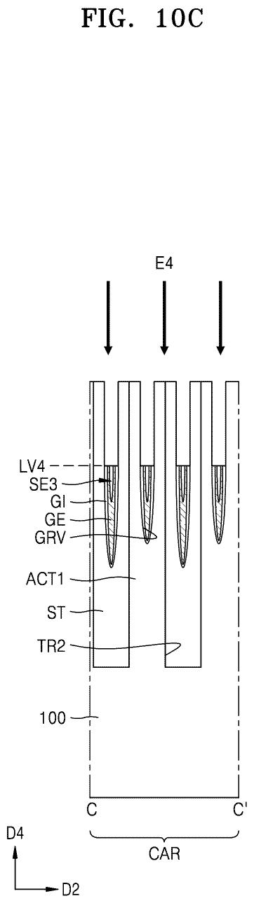

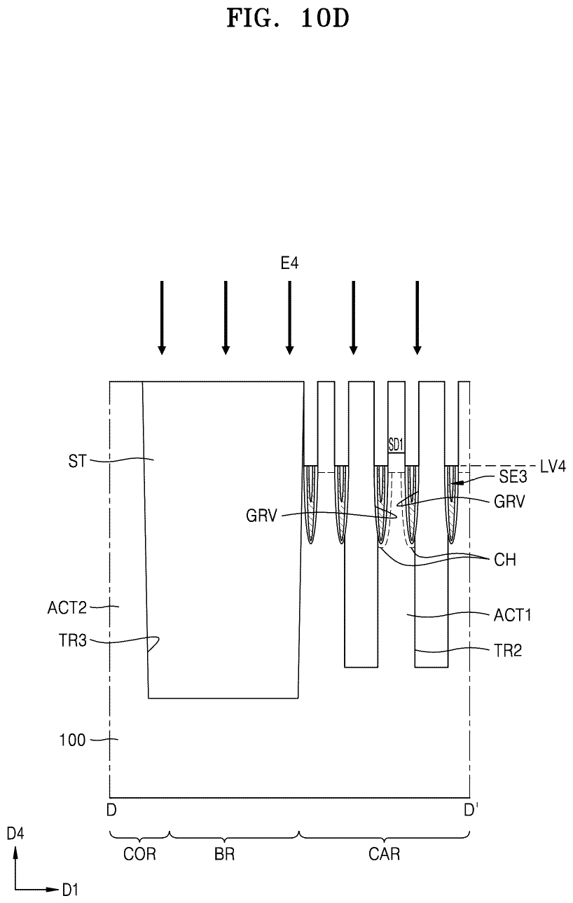

Referring to FIGS. 8 and 10A to 10D, a fourth etching process E4 may be performed on the gate electrode pattern GE. The fourth etching process E4 may be a wet etching process. A portion of the gate electrode pattern GE and a portion of the gate dielectric pattern GI may be etched due to the fourth etching process E4. Due to the fourth etching process E4, the top surface of the gate electrode pattern GE may have a fourth vertical level LV4. The fourth vertical level LV4 may be lower than the third vertical level LV3.

While the fourth etching process E4 is performed, respective vertical levels of the top surfaces of the plurality of gate electrode patterns GE may be substantially the same as each other. That is, due to the fourth etching process E4, uniformity of the top surfaces of the plurality of gate electrode patterns GE may be improved.

For example, during the third etching process E3 and the fourth etching process E4, the third seam SE3 may not be exposed to the outside. Therefore, the etchant used in the fourth etching process E4 may be limited and/or prevented from penetrating the third seam SE3.

Alternatively, even if the third seam SE3 is exposed to the outside after the third etching process E3, the size of the third seam SE3 may be controlled in the third etching process E3. Therefore, the etchant used in the fourth etching process E4 may be limited and/or prevented from penetrating the third seam SE3. For the above reasons, when the etchant composition according to the embodiments of inventive concepts is used, the size of the third seam SE3 inside the gate electrode pattern GE may be controlled.

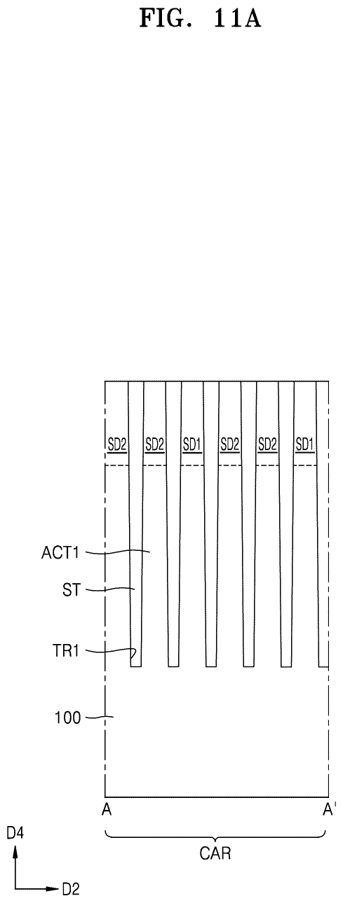

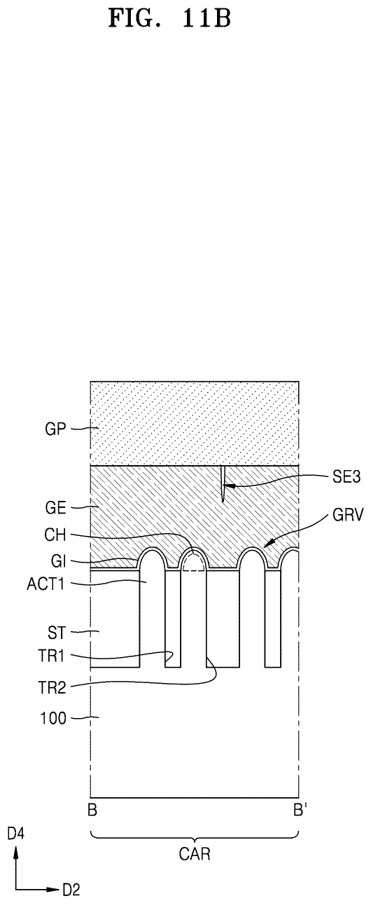

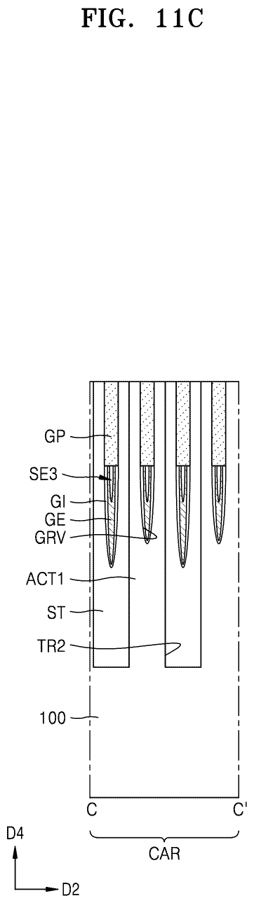

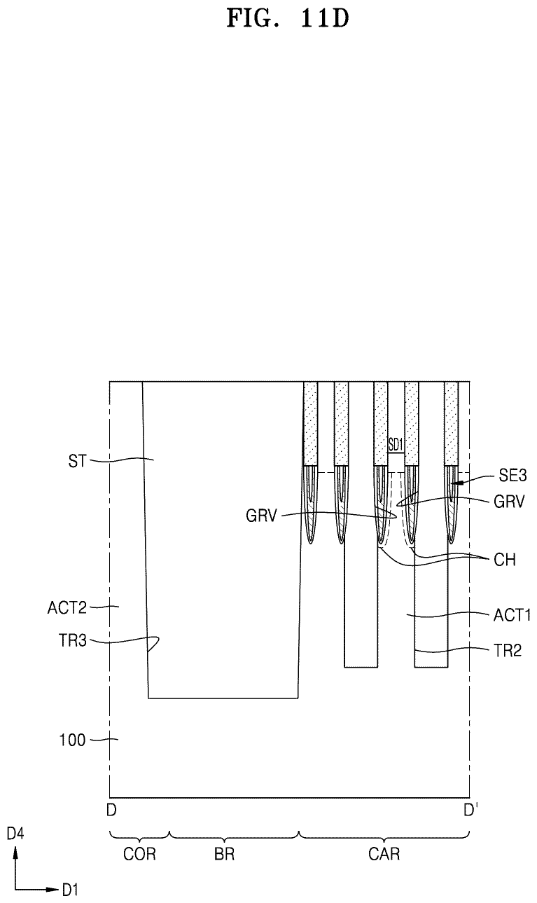

Referring to FIGS. 8 and 11A to 11D, a gate capping layer GP may be formed on each of the gate electrode patterns GE. The top surface of the gate capping layer GP may be coplanar with the top surface of the first active pattern ACT1.

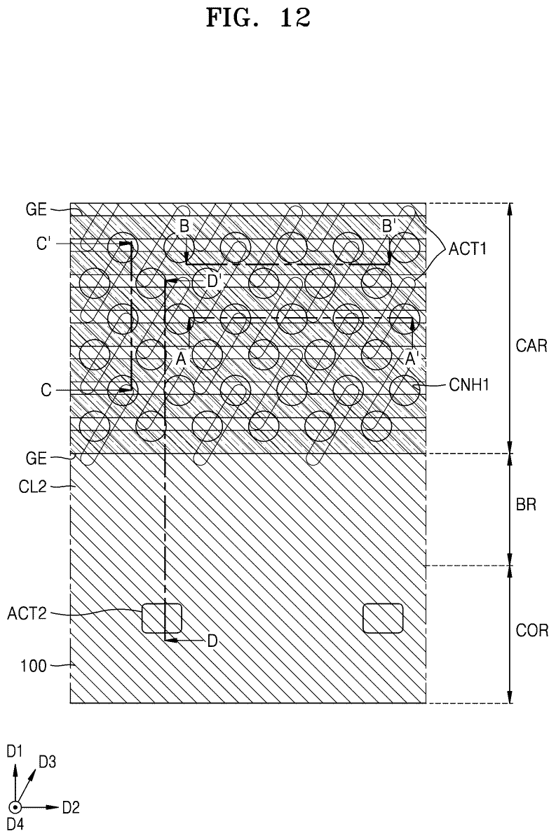

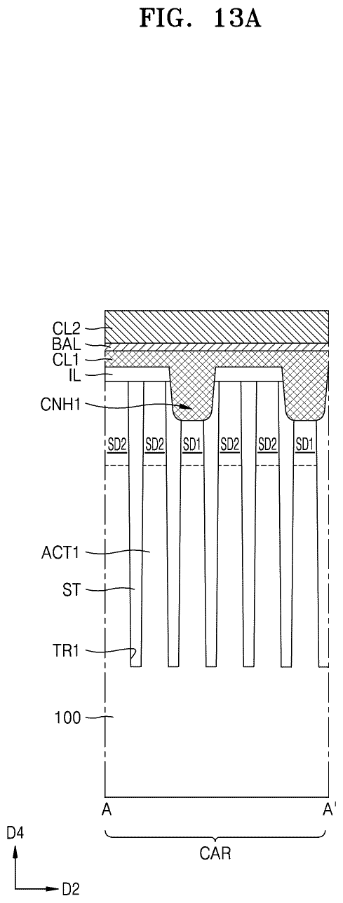

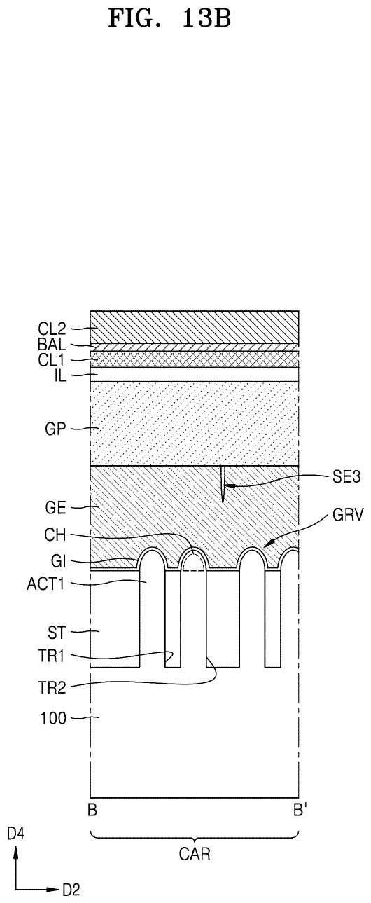

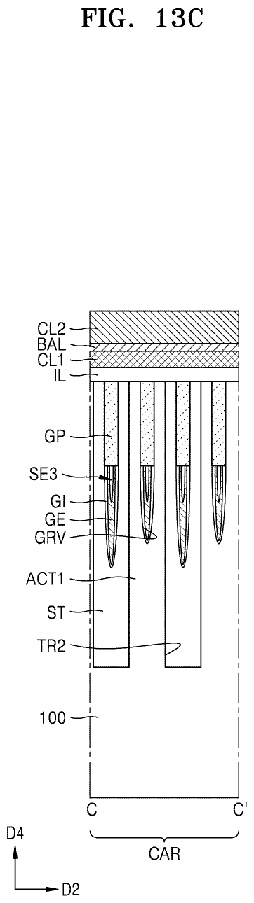

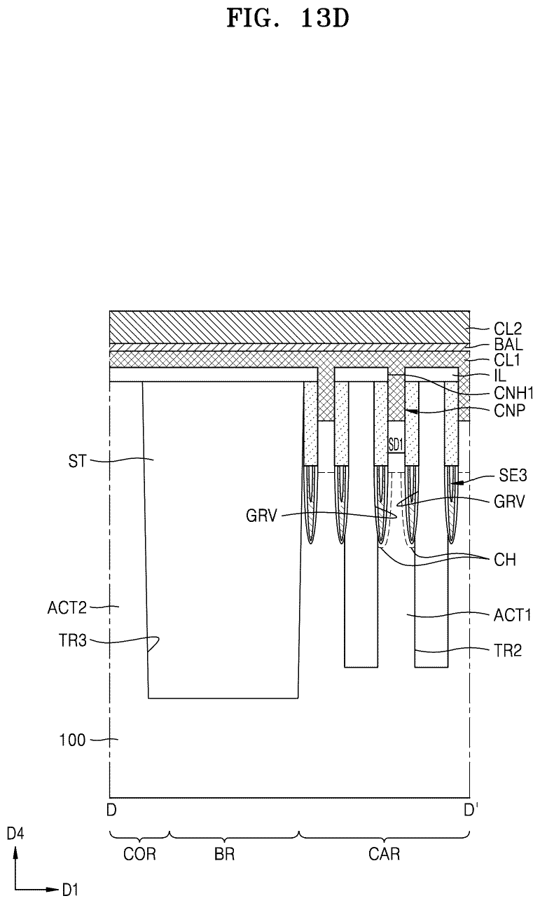

Referring to FIGS. 12 and 13A to 13D, a buffer layer IL may be formed on the entire surface of the substrate 100. In other words, the buffer layer IL may be formed in the cell region CAR, the boundary region BR, and the core region COR. For example, the buffer layer IL may have a multi-layer structure in which a silicon oxide layer and a silicon oxynitride layer are stacked.

The buffer layer IL in the cell region CAR may be patterned to form first contact holes CNH1 exposing the first source/drain regions SD1, respectively, of the first active patterns ACT1. When the first contact holes CNH1 are formed, the upper portions of the first source/drain regions SD1 may be recessed. When the first contact holes CNH1 are formed, the upper portion of the device isolation layers ST around the first source/drain regions SD1 may be recessed.

A first conductive layer CL1, a barrier layer BAL, and a second conductive layer CL2 may be sequentially formed on the buffer layer IL. The first conductive layer CL1, the barrier layer BAL, and the second conductive layer CL2 may be formed in the cell region CAR, the boundary region BR, and the core region COR.

The first conductive layer CL1 may fill the first contact holes CNH1. In other words, the first conductive layer CL1 may be in contact with the first source/drain regions SD1 of the first active patterns ACT1. The first conductive layer CL1 filled in the first contact holes CNH1 may form contact portions CNP. The first conductive layer CL1 may be vertically spaced apart from the second source/drain regions SD2 of the first active patterns ACT1 by the buffer layer IL. The first conductive layer CL1 may include a doped semiconductor material.

The barrier layer BAL may be formed to be arranged between the first conductive layer CL1 and the second conductive layer CL2. The barrier layer BAL may include conductive metal nitride. The second conductive layer CL2 may include a metallic material. The barrier layer BAL may suppress the metallic material in the second conductive layer CL2 from diffusing into the first conductive layer CL1.

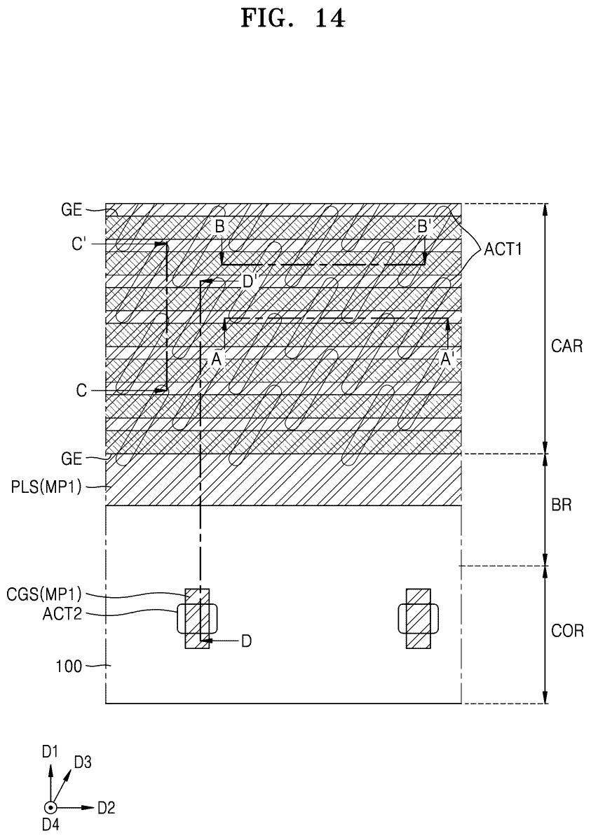

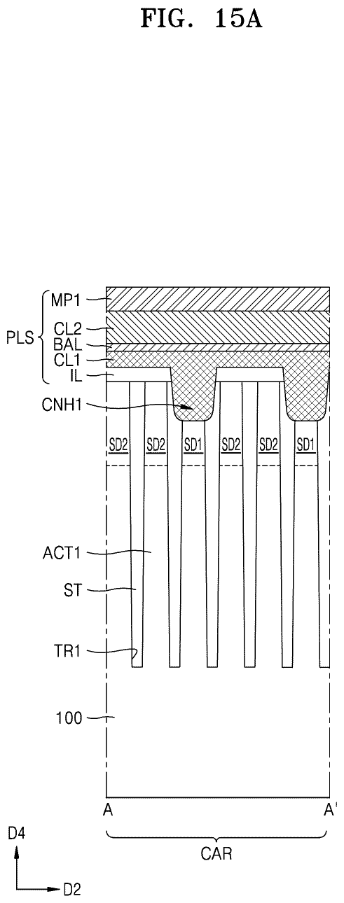

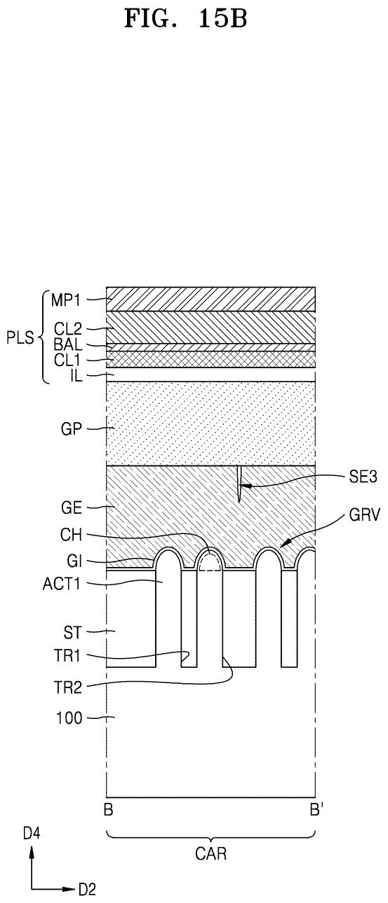

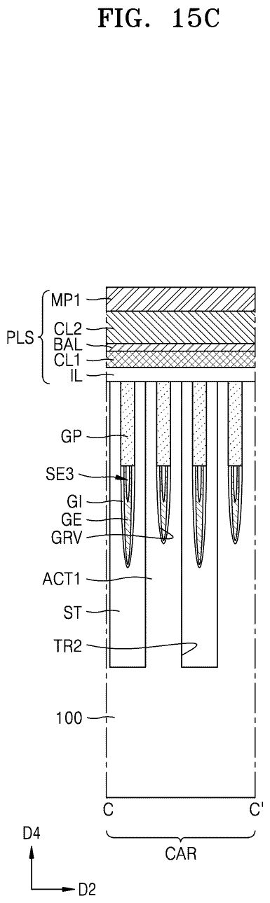

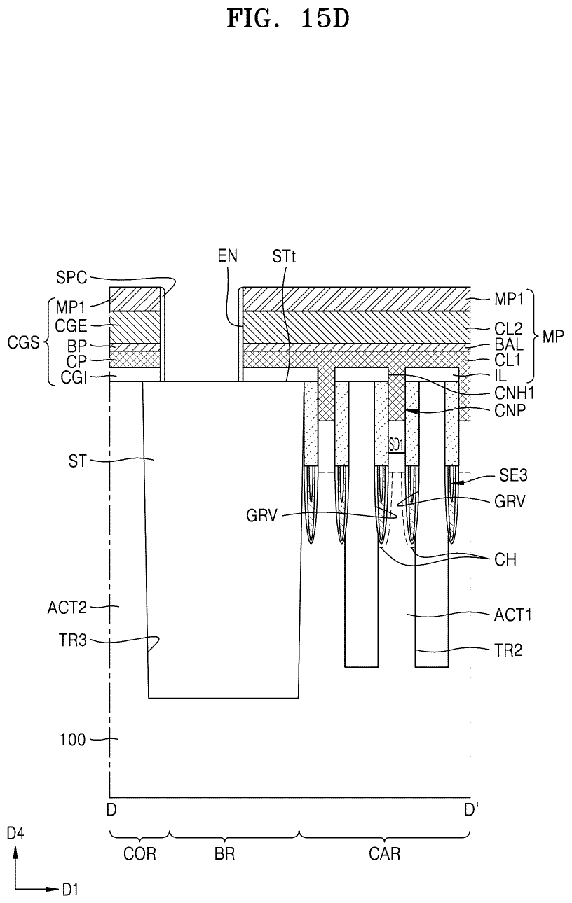

Referring to FIGS. 14 and 15A to 15D, a first mask pattern MP1 may be formed on the second conductive layer CL2. The first mask pattern MP1 may be formed to completely cover the cell region CAR. An edge of the first mask pattern MP1 may overlap the boundary region BR. The first mask pattern MP1 in the core region COR may define a core gate structure CGS. Specifically, the forming of the first mask pattern MP1 may include forming a first mask layer on the second conductive layer CL2, and patterning the first mask layer using photolithography.

The second conductive layer CL2, the barrier layer BAL, the first conductive layer CL1, and the buffer layer IL may be etched using the first mask pattern MP1 as an etch mask. Accordingly, the device isolation layer ST in an area not covered by the first mask pattern MP1 may be exposed.

The buffer layer IL, the first conductive layer CL1, the barrier layer BAL, and the second conductive layer CL2 in the cell region CAR may be patterned by the first mask pattern MP1 to form a plate structure PLS. In a plan view, the plate structure PLS may have a rectangular plate shape. The plate structure PLS may entirely overlap the cell region CAR. An edge of the plate structure PLS may overlap at least a portion of the boundary region BR.

The buffer layer IL, the first conductive layer CL1, the barrier layer BAL, and the second conductive layer CL2 on the second active pattern ACT2 may be patterned by the first mask pattern MP1 to form the core gate structure CGS. The core gate structure CGS may include a core gate insulating layer CGI, a conductive pattern CP, a barrier pattern BP, a core gate electrode CGE, and a first mask pattern MP1, which are sequentially stacked on the second active pattern ACT2.

A sidewall spacer SPC may be formed on one end EN (or a sidewall) on the boundary region BR of the plate structure PLS. A sidewall spacer SPC may be formed on a sidewall of the core gate structure CGS. The forming of the sidewall spacer SPC may include forming a spacer layer on the entire surface of the substrate 100 and anisotropically etching the spacer layer. The sidewall spacer SPC may include silicon oxide.

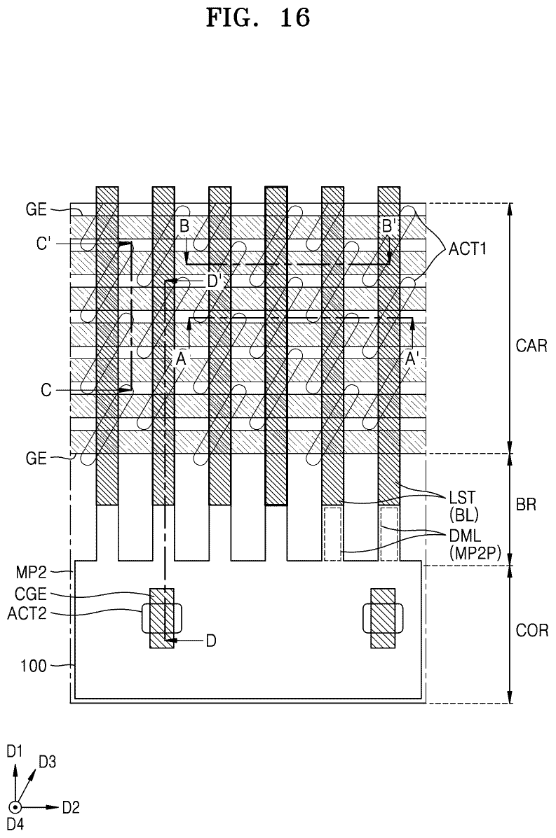

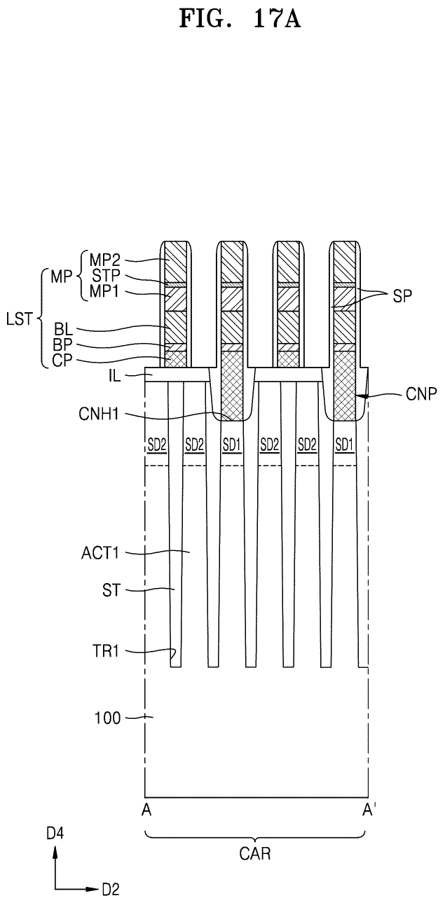

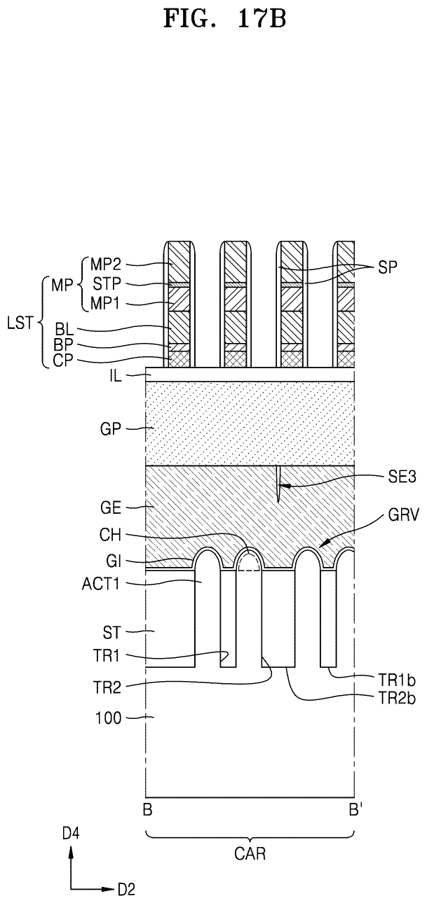

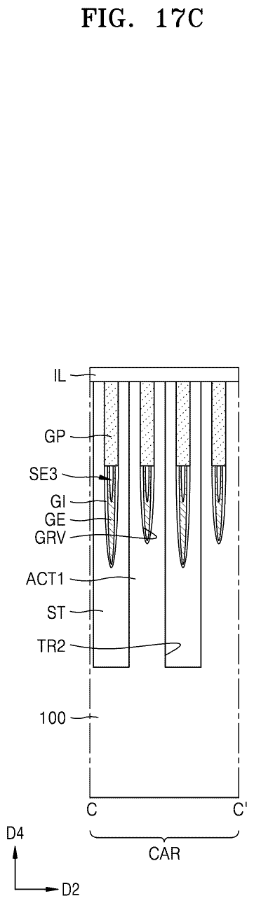

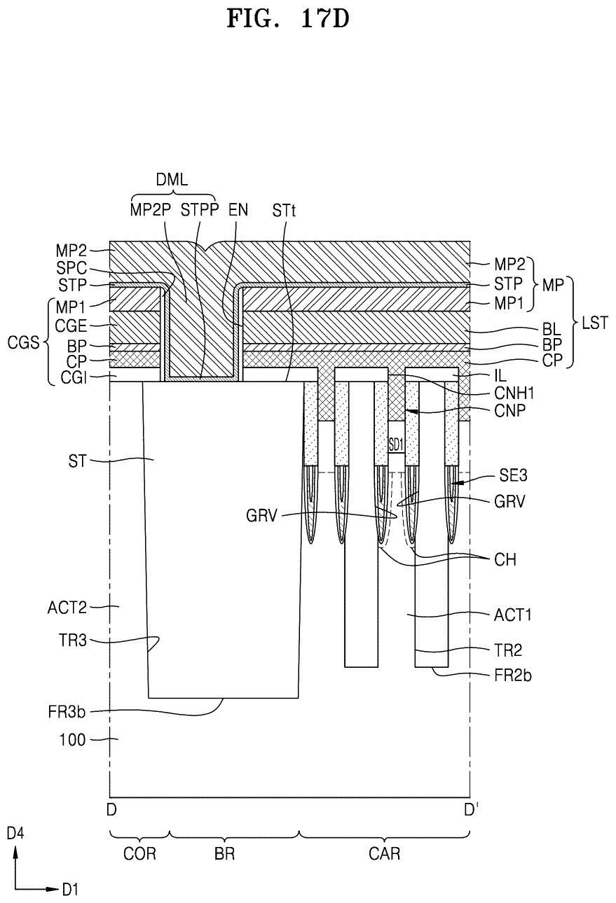

Referring to FIGS. 16 and 17A to 17D, the plate structure PLS in the cell region CAR may be patterned to form line structures LST extending parallel to each other in the first horizontal direction D1. The line structures LST may extend from the cell region CAR to the boundary region BR. A dummy capping pattern DML may be formed on one end EN of each of the line structures LST on the boundary region BR.

Specifically, the forming of the line structures LST and the dummy capping patterns DML may include forming a stopper layer and a second mask layer on the substrate 100, forming a second mask pattern MP2 from the second mask layer using a photolithography process, and patterning the plate structure PLS by using the second mask pattern MP2 as an etching mask.

The stopper layer, the first mask pattern MP1, the second conductive layer CL2, the barrier layer BAL, and the first conductive layer CL1 may be sequentially patterned by using the second mask pattern MP2 in the cell region CAR as an etching mask, to form a stopper pattern STP, a first mask pattern MP1, a bit line BL, a barrier pattern BP, and a conductive pattern CP, respectively.

A plurality of line structures LST may be formed from the plate structure PLS by the second mask pattern MP2 in the cell region CAR. The conductive pattern CP, the barrier pattern BP, the bit line BL, and the mask pattern MP sequentially stacked on the buffer layer IL in the cell region CAR may form a line structure LST. In the cell region CAR, the mask pattern MP may include the first mask pattern MP1, the stopper pattern STP, and the second mask pattern MP2.

In a plan view, each of the bit lines BLs may extend while crossing the gate electrode patterns GE.

A conductive pattern CP of the line structure LST may include contact portions CNP filling the first contact holes CNH1, respectively. The conductive pattern CP may be connected to the first source/drain region SD1 through the contact portion CNP. In other words, the bit line BL may be electrically connected to the first source/drain region SD1 through the conductive pattern CP.

In the boundary region BR, the dummy capping pattern DML may include a first portion STPP and a second portion MP2P. The first portion STPP may be a portion extending from the stopper pattern STP. The first portion STPP may be a portion of the stopper pattern STP. That is, the first portion STPP may be a portion of the stopper pattern STP arranged in the boundary region BR.

Similarly, the second portion MP2P may be a portion in which the second mask pattern MP2 extends. The second portion MP2P may be a portion of the second mask pattern MP2. That is, the second portion MP2P may be a portion of the second mask pattern MP2 arranged in the boundary region BR.

The dummy capping pattern DML may cover one end EN of the line structure LST. While the bit line BL is patterned, the dummy capping pattern DML may limit and/or prevent the bit line BL from being exposed to an oxide environment.

The second mask pattern MP2 in the core region COR may have a plate shape that entirely overlaps the core region COR. The second mask pattern MP2 may cover the top surface of the core gate structure CGS.

A pair of spacers SP may be formed on both sidewalls of each of the dummy capping pattern DML covering the line structure LST and one end EN thereof. The forming of the spacers SP may include forming a spacer layer conformally on the entire surface of the substrate 100, and performing anisotropic etching of the spacer layers.

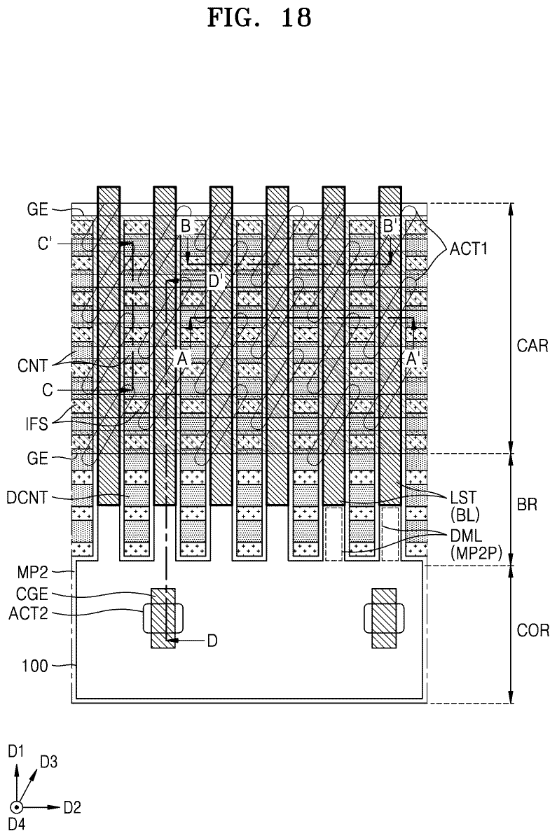

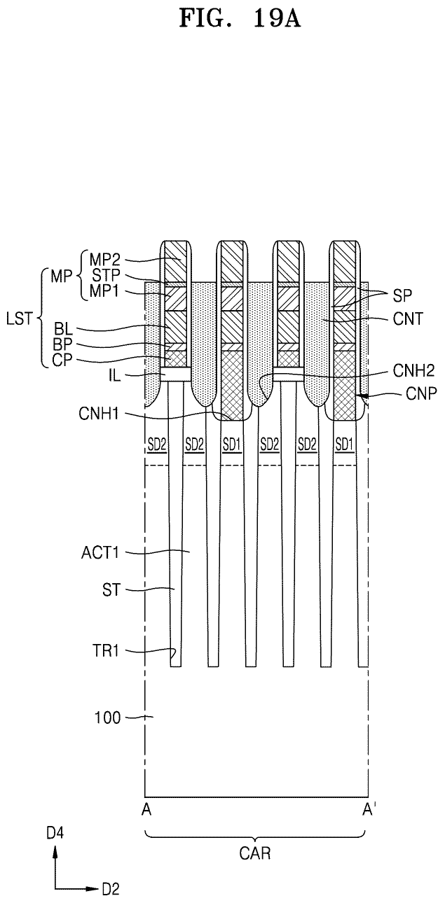

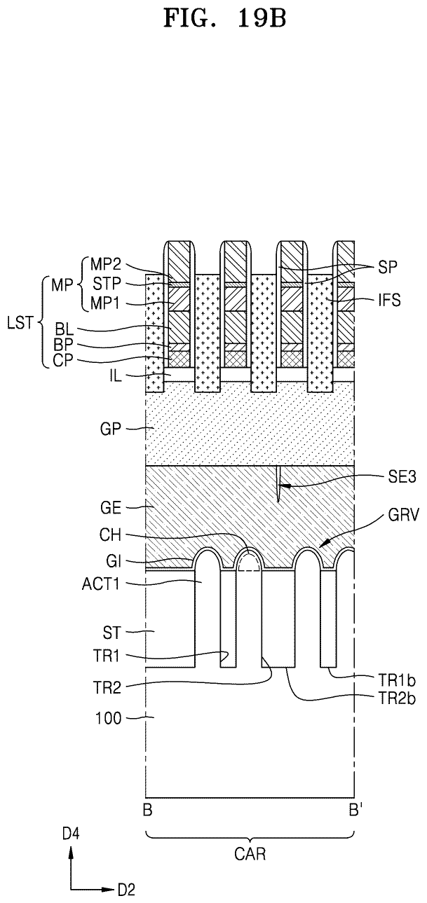

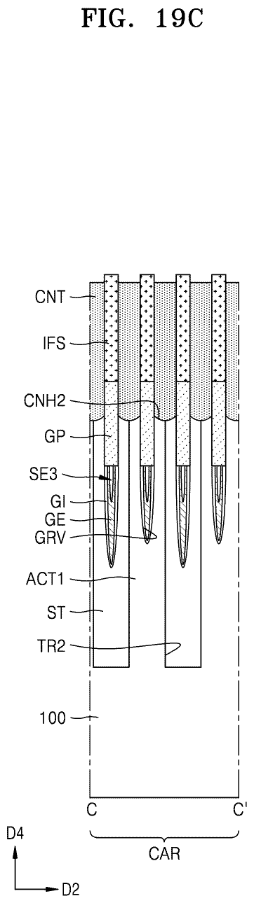

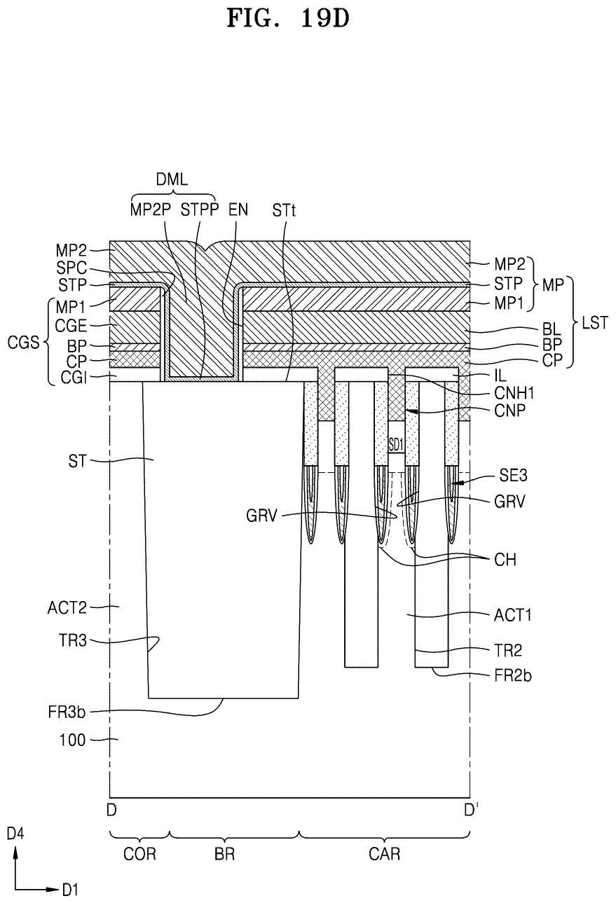

Referring to FIGS. 18 and 19A to 19D, second contact holes CNH2 exposing the second source/drain regions SD2, respectively, may be formed by performing an etching process on the entire surface of the substrate 100 using the spacers SP and mask patterns MP as masks.

Specifically, the second contact holes CNH2 may penetrate the buffer layer IL and extend further downward than the top surface of the substrate 100. When the second contact holes CNH2 are formed, the upper portions of the second source/drain regions SD2 may be recessed. When the second contact holes CNH2 are formed, the upper portions of the device isolation layers ST around the second source/drain regions SD2 may be recessed.

A plurality of insulating fences IFS may be respectively formed between the line structures LST adjacent to each other. The insulating fences IFS may expose the second contact holes CNH2 without overlapping the second contact holes CNH2.

By filling the second contact holes CNH2 with a conductive material, contacts CNT may be formed in the second contact holes CNH2, respectively. The contacts CNT may be connected to the second source/drain regions SD2. Specifically, after the conductive material is formed on the entire surface of the substrate 100, the conductive material may be recessed so that the top surface of the conductive material is lower than the top surfaces of the insulating fences IFS. Thus, the conductive material may be separated by the insulating fences IFS to form contacts CNTs in the second contact holes CNH2, respectively. The contacts CNT and the insulating fences IFS between the line structures LST adjacent to each other may be alternately arranged with respect to each other in the first horizontal direction D1.

The conductive material filled in the second contact holes CNH2 may be a doped semiconductor material. For example, the conductive material may include doped polysilicon. A doped semiconductor may be filled into the second contact holes CNH2, and impurities in the semiconductor may be diffused into the second source/drain regions SD2. Diffusion of the impurities may use a metallurgical process.

Referring back to FIGS. 4 and 5A to 5D, landing pads LP may be formed on the contacts CNT in the cell region CAR, respectively. Specifically, a metal layer may be formed on the contacts CNT and the insulating fences IFS. A plurality of landing pads LP may be formed by patterning the metal layer. An insulating pattern INP may be formed by filling a space among the plurality of landing pads LP with an insulating material.

The data storage elements DS may be provided on the landing pads LP, respectively. The forming of the data storage elements DS may include forming a lower electrode on the landing pad LP, forming a dielectric layer covering the lower electrode, and forming an upper electrode on the dielectric layer. Although not shown, stacked wiring layers may be formed on the data storage elements DS.

While inventive concepts has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
preparing a semiconductor structure;
forming a slit recessed downward in a vertical direction from a top surface of the semiconductor structure, wherein a length of the slit in the vertical direction is greater than a width of the slit in a horizontal direction;
forming a conductive layer filling at least a portion of the slit, wherein the conductive layer includes titanium nitride and a seam in the conductive layer;
performing a first etching process using an etchant composition to etch the conductive layer,
wherein the etchant composition includes an oxidizing agent, an etching agent, an additive, and a solvent, a conductive pattern is formed inside the slit from the conductive layer due to the first etching process, and a vertical level of a top surface of the conductive pattern is lower than a vertical level of a top surface of the semiconductor structure; and
performing a second etching process on the conductive pattern, wherein
the oxidizing agent includes periodic acid, and
the additive includes nitric acid, acetic acid, or a combination thereof.

2. The method of claim 1, wherein
the etching agent includes phosphoric acid, sulfuric acid, or a combination thereof, and
the solvent includes water.

3. The method of claim 2, wherein, based on 100 parts by weight, the etchant composition comprises:
0.1 to 10 parts by weight of the oxidizing agent;
40 to 90 parts by weight of the etching agent;
0 to 1 part by weight of the additive; and
0 to 50 parts by weight of the solvent.

4. The method of claim 1, wherein the seam is not exposed to an outside area after the performing the first etching process.

5. The method of claim 1, wherein the seam is exposed to an outside area after the performing the first etching process.

6. The method of claim 1, wherein the seam is not exposed to an outside area after the performing the second etching process.

7. The method of claim 6, wherein the additive includes acetic acid.

8. The method of claim 1, wherein
a length of the seam in the vertical direction is greater than the width of the seam in the horizontal direction.

9. The method of claim 1, further comprising:
forming a capping pattern on the conductive pattern after the performing the second etching process, wherein
the capping pattern includes a conductive material, an insulating material, or a combination thereof.

10. A method of manufacturing a semiconductor device, the method comprising:
preparing a substrate;
forming active patterns by patterning an upper portion of the substrate;
forming a groove recessed downward in a vertical direction from a top surface of each of the active patterns, wherein a length of the groove in the vertical direction is greater than a width of the groove in a horizontal direction;
sequentially forming a gate dielectric layer and a gate electrode layer in the groove, the gate electrode layer including titanium nitride and being formed on the gate dielectric layer, the gate electrode layer extending on a top surface of each of the active patterns, and the gate electrode layer including a seam in the gate electrode layer;
performing a first etching process on the gate electrode layer using an etchant composition, wherein the etchant composition includes an oxidizing agent, an etching agent, an additive, and a solvent, a gate electrode pattern is formed from the gate electrode layer by the first etching process, and a vertical level of a top surface of the gate electrode pattern is lower than a vertical level of a top surface of each of the active patterns; and
performing a second etching process on the gate electrode pattern.

11. The method of claim 10, wherein
the oxidizing agent includes periodic acid,
the etching agent includes phosphoric acid, sulfuric acid, or a combination thereof,
the additive includes nitric acid, acetic acid, or a combination thereof, and
the solvent includes water.

12. The method of claim 11, wherein, based on 100 parts by weight, the etchant composition comprises:
0.1 to 10 parts by weight of the oxidizing agent;
40 to 90 parts by weight of the etching agent;
0 to 1 part by weight of the additive; and
0 to 50 parts by weight of the solvent.

13. The method of claim 10, wherein the additive includes acetic acid.

14. The method of claim 10, wherein
the forming active patterns by patterning the upper portion of the substrate includes forming trenches in the substrate to define the active patterns and forming a device isolation layer in the trenches before the forming the groove,
after the forming active patterns, the forming the groove includes forming the groove is formed in the device isolation layer.

15. The method of claim 10, wherein the seam is not exposed to an outside area after performing the first etching process.

16. The method of claim 10, wherein the seam is exposed to an outside area after performing the first etching process.

17. The method of claim 10, wherein the seam is not exposed to an outside area after performing the second etching process.

18. The method of claim 10, wherein a length of the seam in the vertical direction is greater than the width of the seam in the horizontal direction.

19. A method of manufacturing a semiconductor device, the method comprising:
preparing a substrate;
forming active patterns by patterning an upper portion of the substrate;
forming a groove recessed downward in a vertical direction from a top surface of each of the active patterns, wherein a length of the groove in the vertical direction is greater than a width of the groove in a first horizontal direction;
sequentially forming a gate dielectric layer and a gate electrode layer in the groove, the gate electrode layer including titanium nitride and being formed on the gate dielectric layer, the gate electrode layer extending on a top surface of each of the active patterns, and the gate electrode layer including a seam in the gate electrode layer;
performing a first etching process on the gate electrode layer using an etchant composition, wherein the etchant composition includes an oxidizing agent, an etching agent, an additive, and a solvent, a gate electrode pattern is formed from the gate electrode layer by the first etching process, the electrode pattern extends in a second horizontal direction crossing the first horizontal direction, and a vertical level of a top surface of the gate electrode pattern is lower than a vertical level of a top surface of each of the active patterns;
performing a second etching process on the gate electrode pattern;
forming a gate capping layer on the gate electrode pattern;
forming line structures extending in the first horizontal direction on a top surface of the gate capping layer, wherein the line structures are spaced apart from each other in the second horizontal direction; and
forming insulating fences between the line structures adjacent to each other in the second horizontal direction.

20. The method of claim 19, wherein
the oxidizing agent includes periodic acid,
the etching agent includes phosphoric acid, sulfuric acid, or a combination thereof,
the additive includes nitric acid, acetic acid, or a combination thereof,
the solvent includes water, and
based on 100 parts by weight, the etchant composition includes
0.1 to 10 parts by weight of the oxidizing agent,
40 to 90 parts by weight of the etching agent,
0 to 1 part by weight of the additive, and
0 to 50 parts by weight of the solvent.
